(19) United States
(12) Patent Application Publication
(10) Pub. No.: US 2014/0090692 A1
(43) Pub. Date: Apr. 3, 2014

(54) CONCENTRATED SOLAR CELL AND MANUFACTURING METHOD FOR THE SAME

(71) Applicants: Chikao Okamoto, Osaka-shi (JP); Kohsuke Ueda, Osaka-shi (JP)

(72) Inventors: Chikao Okamoto, Osaka-shi (JP); Kohsuke Ueda, Osaka-shi (JP)

(73) Assignee: SHARP KABUSHIKI KAISHA, Osaka-shi,Osaka (JP)

(21) Appl. No.: 14/119,020

(22) PCT Filed: May 11, 2012
(86) PCT No.: PCT/JP2012/062152

§ 371 Date: Nov. 20, 2013

(30) Foreign Application Priority Data
May 20, 2011 (JP) 2011-113815

(51) Int. Cl. H01L 31/052

(52) U.S. Cl. CPC H01L 31/0524
USPC 136/246; 136/259; 136/255; 438/65

(57) ABSTRACT

A concentrated solar cell has a sealing portion (12) provided on a receiver substrate (102) so as to cover a solar cell element (101) provided on the receiver substrate (102), and an optical member (13) that is provided on the sealing portion (12) and concentrates sunlight on the solar cell element (101). The optical member (13) is configured so as to include an optical refraction portion (131) having a curved face for refracting and concentrating sunlight, a concentrated light emission portion (133) that is arranged in close contact with the sealing portion (12) such that the sunlight concentrated by the optical refraction portion (131) is emitted toward the solar cell element (101), and an optical base portion (132) arranged between the optical refraction portion (131) and the concentrated light emission portion (133). Also, the optical member (13) has an integrated structure in which there is no intermediate air layer from the optical refraction portion (131) to the concentrated light emission portion (133) with the optical base portion (132) therebetween.

### TECHNICAL FIELD

The present invention relates to a concentrated solar cell that includes an integrated-structure optical member that improves sunlight concentration efficiency and suppresses a reduction in output caused by sun tracking error, and a manufacturing method for the same.

### BACKGROUND ART

Conventional solar power generation devices have generally had a non-concentrating fixed flat-plate structure in which solar cell elements are laid out without gaps to configure a solar power generation module for installation on a roof or the like.

Also, in recent years, technology has been proposed for reducing the usage of solar cell elements, which are expensive among the members (parts) configuring a solar power generation device.

Specifically, there has been a proposal for concentrating sunlight using optical lenses, reflecting mirrors, and the like, and irradiating a small-area solar cell element with the concentrated light in order to increase the amount of power generated per unit of solar cell element area and reduce the cost of the solar cell element (i.e., the cost of the solar power generation device).

One characteristic of a solar cell element is that the photoelectric conversion efficiency improves as the concentration power is raised. However, if the position of a solar cell element is fixed, the sunlight is almost incident at an oblique angle, and sunlight cannot be used effectively. For this reason, there has been a proposal for a tracking concentrated solar power generation device with a high concentration power that is configured so as to always receive sunlight from the front by tracking the sun (e.g., see Patent Document 1).

FIGS. 13 and 14 are cross-sectional diagrams showing the configuration of a concentrated solar power generation module that is applied to a conventional tracking concentrated solar power generation device.

The conventional concentrated solar power generation module has a structure in which a concentrating lens 50 that receives and concentrates sunlight Ls and a solar cell 70 that receives sunlight Lsc (see FIG. 13) concentrated by the concentrating lens 50 and subjects it to photoelectric conversion are arranged using a substantially conical module frame 90 so as to oppose each other across a predetermined distance. The solar cell 70 has a structure in which a solar cell element 702 is placed on a receiver substrate 701, cover glass 703 is placed on the receiver substrate 701 so as to cover the solar cell element 702, and the solar cell element 702 is resin-sealed by filling the interior of the cover glass 703 with translucent sealing resin 704.

Also, the concentrating lens 50 is a Fresnel lens in which an exit portion 50a on the side opposing the solar cell element 702 (the lower face side in the figure) is divided into concentric circles centered about the lens central portion (centerline C2) so as to form multiple ring-shaped lens faces 50a1, 50a2, . . . , 50an, and so on, and the angles of inclination of the ring-shaped lens faces 50a1, 50a2, . . . , 50an, and so on are set such that the sunlight Lsc refracted by the ring-shaped lens faces 50a1, 50a2, . . . , 50an, and so on travels toward a light receiving face 702a of the solar cell element 702.

### CITATION LIST

### Patent Document

[Patent Document 1] JP 2009-266890A

### SUMMARY OF INVENTION

### Technical Problem

When sunlight is concentrated by the concentrating lens 50 in this type of conventional tracking concentrated solar power generation device, there is an intermediate air layer 63 that is a space between the concentrating lens 50 and the solar cell 70. As a result, the sunlight Ls that is incident on the concentrating lens 50 undergoes light intensity reflection at the interface between an emission portion 50a of the concentrating lens 50 and the intermediate air layer 63, and the concentration efficiency decreases. Similarly, the concentrated light also undergoes light intensity reflection at the interface between the intermediate air layer 63 and the cover glass 703, thus further reducing the concentration efficiency.

Also, in the conventional tracking concentrated solar power generation device, when the sunlight Ls is concentrated by the concentrating lens 50, the difference between the refractive indices at the various wavelengths of sunlight causes so-called chromatic aberration, which is a phenomenon in which the concentrating position is different between long wavelength light Lsc1 and short wavelength light Lsc2 as shown in FIG. 14, to occur on the light receiving face 702a of the solar cell element 702, and the output decreases depending on the type of solar cell element 702.

Furthermore, in the conventional tracking concentrated solar power generation device, when the sunlight that passes through the concentrating lens 50 is concentrated, it is refracted by the interface (emission portion 50a) when it enters the intermediate air layer 63, which is a low refractive index portion n1, from the concentrating lens 50, which is a high refractive index portion n2, and therefore the angle of refraction increases. As a result, in the case of sunlight Lsv that deviates somewhat from the perpendicular direction due to several degrees of sun tracking error as shown in FIG. 13, the spot position of a focal point group 30′ for light concentrated by the concentrating lens 50 deviates from the solar cell element 702, and the receiver substrate 701 is directly irradiated by the concentrated light focal point group 30′.

Furthermore, in order to precisely align the center of the concentrating lens 50 and the center of the solar cell element 702, positioning portions (not shown) that serve as alignment references are formed on both the concentrating lens 50 and the receiver substrate 701, and the positioning portion provided on the concentrating lens 50 needs to be aligned with the positioning portion provided on the receiver substrate 703, which complicates the procedure and increases the number of processing steps.

The present invention has been achieved in light of such a situation, and a main object thereof is to provide a concentrated solar cell that improves output by efficiently concentrating sunlight on an solar cell element due to providing an optical member that has an integrated structure in which a concentrating lens and a solar cell are integrated in order to eliminate light intensity reflection that has been a cause for a reduction in concentration efficiency, and to provide a manufacturing method for the same.

### Solution to Problem

In order to solve the above-described issues, a concentrated solar cell according to the present invention is a concentrated solar cell including an element substrate, a solar cell element provided on the element substrate, a sealing portion provided on the element substrate so as to cover the solar cell element, and an optical member that is provided on the sealing portion and concentrates sunlight on the solar cell element, the optical member being configured so as to include: an optical refraction portion that has a curved face for refracting and concentrating sunlight; a concentrated light emission portion that is arranged in close contact with the sealing portion such that sunlight concentrated by the optical refraction portion is emitted toward the solar cell element; and an optical base portion arranged between the optical refraction portion and the concentrated light emission portion, and the optical member being an integrated structure in which there is no intermediate air layer from the optical refraction portion to the concentrated light emission portion with the optical base portion therebetween.

According to this invention, it is possible to eliminate the intermediate air layer that exists in the structure of conventional concentrated solar cells. Accordingly, it is possible to eliminate a reduction in performance caused by light intensity reflection that occurs as a result of a large difference between refractive indices caused by the existence of an intermediate air layer, thus enabling improving the output of the concentrated solar cell.

Alternatively, a concentrated solar cell according to the present invention is a concentrated solar cell including an element substrate, a plurality of solar cell elements provided on the element substrate, a plurality of sealing portions provided on the element substrate so as to individually and respectively cover the solar cell elements, and an optical member that concentrates sunlight on each of the solar cell elements, the optical member having a plurality of optical portions that respectively correspond to the plurality of solar cell elements provided on the element substrate, the optical portions each including: an optical refraction portion that has a curved face for refracting and concentrating sunlight; a concentrated light emission portion that is arranged in close contact with one of the sealing portions such that sunlight concentrated by the optical refraction portion is emitted toward one of the solar cell elements; and an optical base portion arranged between the optical refraction portion and the concentrated light emission portion, and the optical portions each being an integrated structure in which there is no intermediate air layer from the optical refraction portion to the concentrated light emission portion with the optical base portion therebetween.

According to this invention as well, it is possible to eliminate the intermediate air layer that exists in the structure of conventional concentrated solar cells. Accordingly, it is possible to eliminate a reduction in performance caused by light intensity reflection that occurs as a result of a large difference between refractive indices caused by the existence of an intermediate air layer, thus enabling improving the output of the concentrated solar cell.

Also, in the concentrated solar cell according to the present invention, an outer peripheral face of the optical base portion may be arranged outside an optical path of refracted light obtained when sunlight that is incident on a light receiving face of the solar cell element is refracted by the optical refraction portion.

According to this configuration, the shape of the outer peripheral faces of the optical base portion is a prism with a square-shaped bottom face, for example, and the optical refraction portion is the same size as the outer shape of the optical base portion, and therefore the portion of the optical base portion in the periphery of the concentrated light emission portion is not in the optical path of refracted light (concentrated light) that was refracted by the optical refraction portion. In other words, the outer peripheral faces of the optical base portion are arranged outside the optical path of the refracted light (concentrated light). For this reason, the portion of the optical base portion in the periphery of the concentrated light emission portion can be used as a support portion, and using the later-described support member enables placing the optical member at a precise position on the solar cell element, and improving the reliability and weather resistance.

Also, in the concentrated solar cell according to the present invention, the curved face of the optical refraction portion may be dome-shaped or Fresnel lens-shaped.

According to this configuration, the sunlight concentrated by the optical refraction portion has a low angle of refraction since it is concentrated by undergoing refraction when passing from a low refractive index portion n1, which is an air layer, to a high refractive index portion n2, which is the optical refraction portion, and as a result, it is possible to reduce tracking error and misalignment of the spot position of the concentrated light focal point group occurring due to tracking error, thus making it possible to improve the output stability of the solar cell, reliability, and weather resistance.

Also, in the concentrated solar cell according to the present invention, the optical member may be formed from a glass material or at least one resin material from among silicone resin, acrylic resin, fluorine resin, and epoxy resin. This enables obtaining an optical member having superior heat resistance and moisture resistance.

Also, the concentrated solar cell according to the present invention may be configured such that the optical member is formed from a glass material with a refractive index of 1.5 to 1.7, and the ratio of the width of the concentrated light emission portion to the length from a top portion of the optical refraction portion to the concentrated light emission portion is 1:1.5 to 1:3.

According to this configuration, even if sun tracking error occurs or misalignment occurs when the optical member is assembled, it is possible to obtain a high-quality and high-efficiency solar cell without leading to a reduction in output.

Also, the concentrated solar cell according to the present invention may be configured such that a spot position of a concentrated light focal point group of sunlight concentrated by the optical member is located within the light receiving face of the solar cell element.

According to this configuration, even if sun tracking error occurs or misalignment occurs when the optical member is assembled, it is possible to obtain a high-quality and high-efficiency solar cell without leading to a reduction in output.

Also, in the concentrated solar cell according to the present invention, the concentrated light emission portion and the solar cell element may be adhered together using at least one resin material from among silicone resin, acrylic resin, fluorine resin, and epoxy resin.

By adhering the concentrated light emission portion and the solar cell element together using at least one resin material from among silicone resin, acrylic resin, fluorine resin, and epoxy resin, it is possible to prevent the entrance of moisture and water into the solar cell element, thus enabling improving the reliability and weather resistance. Also, according to this configuration, it is possible to reduce the difference between the refractive indices of the integrated-structure optical member and the solar cell element, thus enabling obtaining a high-efficiency solar cell without reducing the amount of light that is incident on the solar cell element.

Also, the concentrated solar cell according to the present invention may be configured such that a columnar optical portion is formed on the concentrated light emission portion, and the portion of the concentrated light emission portion that is arranged in close contact with the sealing portion is a tip portion of the columnar optical portion.

This configuration enables eliminating the intermediate air layer that exists in the structure of conventional concentrated solar cells. Specifically, it is possible to eliminate a reduction in performance caused by light intensity reflection that occurs as a result of a large difference between refractive indices caused by the existence of an intermediate air layer, thus enabling improving the output of the solar cell.

Also, in the concentrated solar cell according to the present invention, the columnar optical portion may be provided so as to gradually decrease in cross-sectional size from an upper end portion on the concentrated light emission portion side toward the tip portion. More specifically, a peripheral side face of the columnar optical portion may have an angle of inclination of 0 degrees to 20 degrees relative to a centerline of the columnar optical portion.

In this way, by forming the peripheral side faces of the columnar optical portion as inclined faces, concentrated light that is incident on the columnar optical portion is guided to the light receiving face of the solar cell element while repeatedly undergoing total reflection at the side faces of the columnar optical portion. This results in the elimination of chromatic aberration on the light receiving face of the solar cell element, and intensity fluctuation as well, thus making it possible to improve the output of the solar cell.

Also, in the concentrated solar cell according to the present invention, the tip portion of the columnar optical portion and the solar cell element may be adhered together using at least one resin material from among silicone resin, acrylic resin, fluorine resin, and epoxy resin.

By adhering the tip portion of the columnar optical portion and the solar cell element together using at least one resin material from among silicone resin, acrylic resin, fluorine resin, and epoxy resin, it is possible to prevent the entrance of moisture and water into the solar cell element, thus enabling improving the reliability and weather resistance. Also, according to this configuration, it is possible to reduce the difference between the refractive indices of the integrated optical member and the solar cell element, thus enabling obtaining a high-efficiency solar cell without reducing the amount of light that is incident on the solar cell element.

Also, the concentrated solar cell according to the present invention may be configured such that a spot position of a concentrated light focal point group of sunlight concentrated by the optical member having the columnar optical portion is located within an upper end face of the columnar optical portion.

According to this configuration, even if sun tracking error occurs or misalignment occurs when the optical member is assembled, it is possible to obtain a high-quality and high-efficiency solar cell without leading to a reduction in output.

Also, in the concentrated solar cell according to the present invention, the tip portion of the columnar optical portion may be formed with a size according to which the tip portion is located within the light receiving face of the solar cell element.

According to this configuration, even if sun tracking error occurs or misalignment occurs when the optical member is assembled, it is possible to obtain a high-quality and high-efficiency solar cell without leading to a reduction in output.

Also, in the concentrated solar cell according to the present invention, a compound multi-junction solar cell may be used as the solar cell element. Using a compound multi-junction solar cell in which junction is performed in the depth direction enables subjecting a wide range of wavelengths to photoelectric conversion, thus making it possible to improve the conversion efficiency.

Also, the concentrated solar cell according to the present invention may be configured so as to include a support member that supports and fixes the optical member on the element substrate. More specifically, a configuration is possible in which the support member includes a support substrate on which the element substrate is placed, and a support part that is provided upright on the support substrate and supports an outer peripheral portion of a lower portion of the optical member.

Including this support member enables the optical member to be precisely and reliably placed and supported on the element substrate.

Also, the concentrated solar cell according to the present invention may be configured such that the support part additionally functions as a positioning member that places the element substrate at a precise position on the support substrate.

Due to the support part additionally functioning as a positioning member, the optical member can be precisely and reliably placed and supported on the element substrate.

Also, a manufacturing method for a concentrated solar cell according to the present invention is a manufacturing method for a concentrated solar cell in which a solar cell element is provided on an element substrate, a sealing portion is provided on the element substrate so as to cover the solar cell element, an integrated-structure optical member that concentrates sunlight on the solar cell element is provided on the sealing portion, and the element substrate and the optical member are integrally supported and fixed by a support member, the method including: a step of mounting the solar cell element on the element substrate; a step of placing the element substrate, on which the solar cell element is mounted, on a support substrate of the support member; a step of forming the sealing portion on an upper portion of the solar cell element; a step of supporting the optical member using a support part provided on the support substrate; and a step of adhering and fixing the sealing portion and the optical member using an adhesive material.

According to this manufacturing method of the present invention, it is possible to simplify the procedure and productively manufacture a highly reliable and high-efficiency concentrated solar cell having superior heat resistance.

Alternatively, a manufacturing method for a concentrated solar cell according to the present invention is a manufacturing method for a concentrated solar cell in which a plurality of solar cell elements are provided on an element substrate, a plurality of sealing portions are provided on the element substrate so as to individually and respectively cover the solar cell elements, an optical member having a plurality of integrated-structure optical portions that respectively correspond to the solar cell element and concentrate sunlight on the respective solar cell elements is provided on the sealing portions, and the element substrate and the optical member are integrally supported and fixed by a support member, the method including: a step of mounting the plurality of solar cell elements on the element substrate; a step of placing the element substrate, on which the plurality of solar cell elements are mounted, on a support substrate of the support member; a step of forming the sealing portions on upper portions of the respective solar cell elements; a step of supporting the optical member using a support part provided on the support substrate; and a step of adhering and fixing the sealing portions and the optical member using an adhesive material.

According to this manufacturing method of the present invention as well, it is possible to simplify the procedure and productively manufacture a highly reliable and high-efficiency concentrated solar cell having superior heat resistance.

### Advantageous Effects of the Invention

According to a concentrated solar cell of the present invention, the optical member is given an integrated structure in which the intermediate air layer is eliminated, thus enabling efficiently concentrating sunlight concentrated by an optical refraction portion without the concentrated sunlight undergoing intensity reflection, and this makes it possible to improve the output characteristic of the solar cell.

### BRIEF DESCRIPTION OF DRAWINGS

FIG. 1 is an exploded perspective view of constituent members of a concentrated solar cell according to Embodiment 1 of the present invention.

FIG. 2 is a side view showing a partially fractured view of the concentrated solar cell according to Embodiment 1 of the present invention.

FIG. 3A is a perspective view of an optical member according to Embodiment 1 as viewed obliquely from above.

FIG. 3B is a perspective view of the optical member according to Embodiment 1 as viewed from the bottom face side.

FIG. 4 is a side view showing a partially fractured view of the concentrated solar cell, and illustrates the optical path of sunlight that is incident on the optical member somewhat deviated from the perpendicular direction.

FIG. 5 is an exploded perspective view of a concentrated solar cell, and shows a support member according to another working example.

FIG. 6 is a side view showing a partially fractured view of a concentrated solar cell according to Embodiment 2 of the present invention.

FIG. 7 is a side view showing a partially fractured view of the concentrated solar cell according to Embodiment 2 of the present invention.

FIG. 8A is a perspective view of an optical member according to Embodiment 2 as viewed obliquely from above.

FIG. 8B is a perspective view of the optical member according to Embodiment 2 as viewed from the bottom face side.

FIG. 9 is a side view showing a partially fractured view of the concentrated solar cell, and shows an example of another shape for an optical refraction portion of the optical member.

FIG. 10 is a side view showing a partially fractured view of a concentrated solar cell according to Embodiment 3 of the present invention.

FIG. 11 is a perspective view of the arrangement of solar cell elements on a receiver substrate in the concentrated solar cell according to Embodiment 3 of the present invention.

FIG. 12A is a perspective view of an optical member according to Embodiment 3 as viewed obliquely from above.

FIG. 12B is a perspective view of the optical member according to Embodiment 3 as viewed from the bottom face side.

FIG. 13 is a cross-sectional diagram showing the configuration of a concentrated solar power generation module that is applied to a conventional tracking concentrated solar power generation device.

FIG. 14 is a cross-sectional diagram showing the configuration of the concentrated solar power generation module that is applied to the conventional tracking concentrated solar power generation device.

### DESCRIPTION OF EMBODIMENT

Embodiments of the present invention will be described below with reference to the drawings.

### Embodiment 1

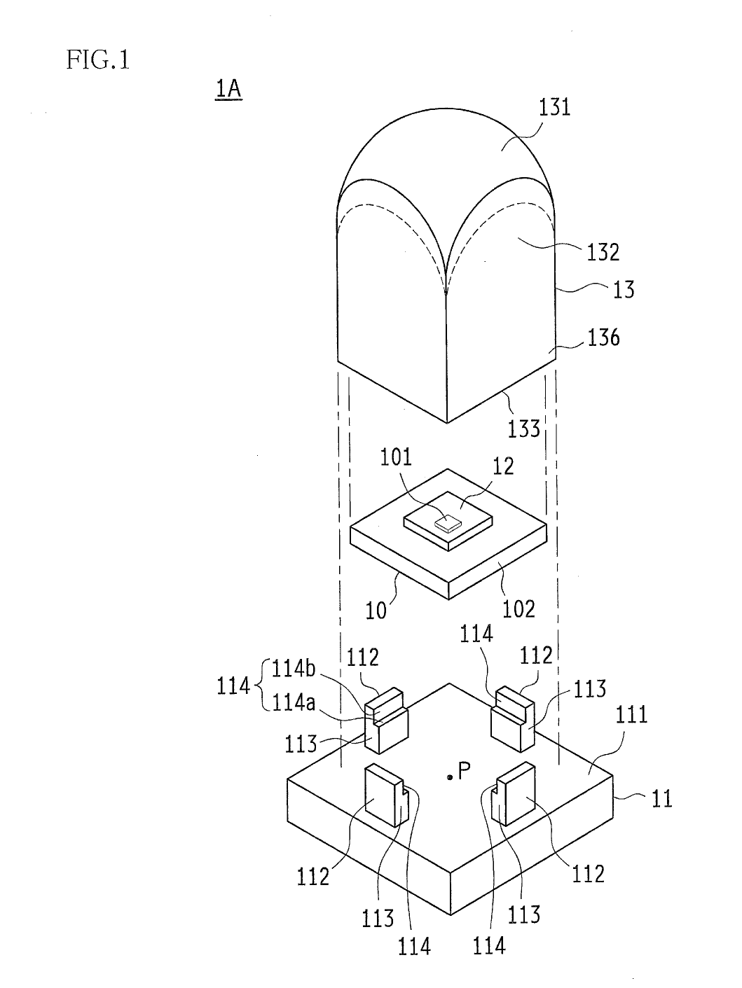

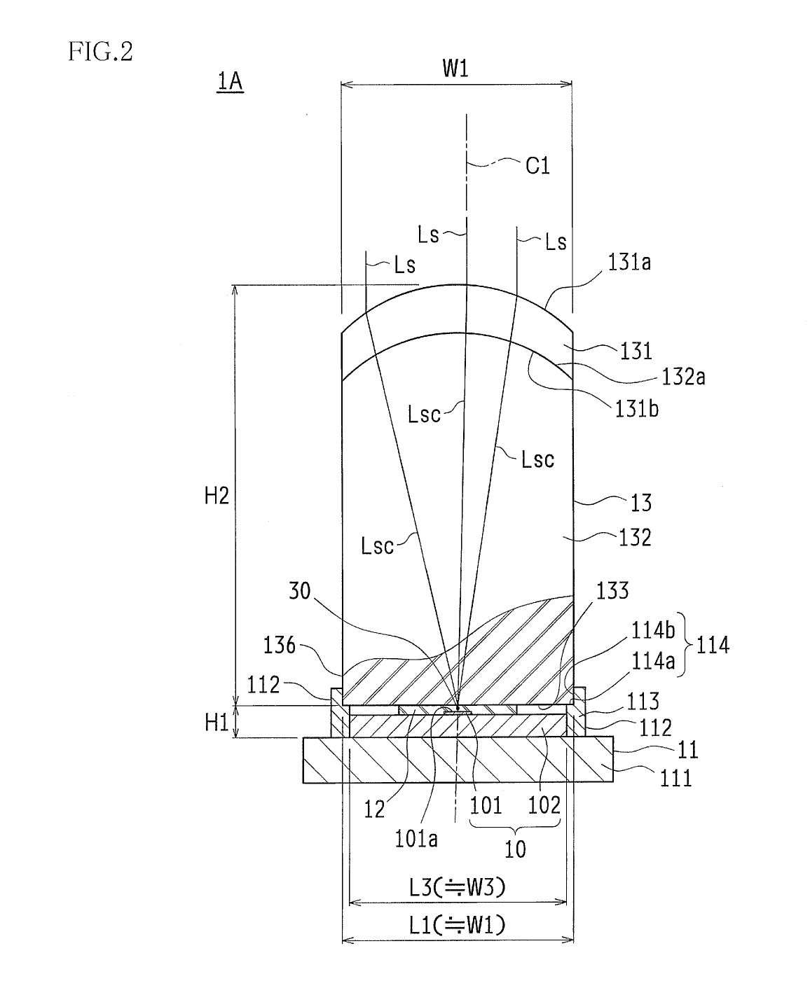

FIG. 1 is an exploded perspective view of constituent members of a concentrated solar cell according to Embodiment 1, and FIG. 2 is a side view showing a partially fractured view of the concentrated solar cell according to Embodiment 1.

A concentrated solar cell 1A according to Embodiment 1 is configured so as to include a solar cell substrate 10, which is obtained by mounting a solar cell element 101 on a receiver substrate (element substrate) 102, a sealing portion 12 provided on the receiver substrate 102 so as to cover the solar cell element 101, an integrated-structure optical member 13 that is provided on the sealing portion 12 and concentrates sunlight on the solar cell element 101, and a support member 11 that integrally supports the receiver substrate 102 and the optical member 13.

The solar cell element 101 is constituted by an inorganic material such as Si, GaAs, CuInGaSe, or CdTe. Also, various modes of structures can be applied to the solar cell element 101, such as a single junction cell, a monolithic multi-junction cell (compound multi-junction solar cell), or a mechanical stacked cell obtained by connecting various types of solar cells having different wavelength sensitivity ranges.

Note that it is preferable for the external size of the solar cell element 101 to be approximately several hundred μm to several mm from the viewpoint of reducing the amount of solar cell material that is used, ease of working, procedure facilitation and simplification, and reducing the amount of material constituting the optical member 13, for example.

The receiver substrate 102 is obtained by forming desired wiring (although not shown, a connection pattern for connection to electrodes of the solar cell element 101 and the extraction of current to the outside, and a connection pattern for connecting solar cells together in series or in parallel, for example) on a base foundation constituted by an aluminum plate, a copper plate, or the like via an appropriate insulating layer made of a ceramic, glass, or the like.

Specifically, in this configuration, current generated by the solar cell element 101 is appropriately extracted to the outside of the solar cell by wiring formed in the receiver substrate 102. Since highly reliably insulation needs to be ensured for the wiring formed in the receiver substrate 102, in this configuration, connection patterns formed from copper foil or the like are insulated by being covered with an insulating film made of an organic material, an inorganic material, or the like.

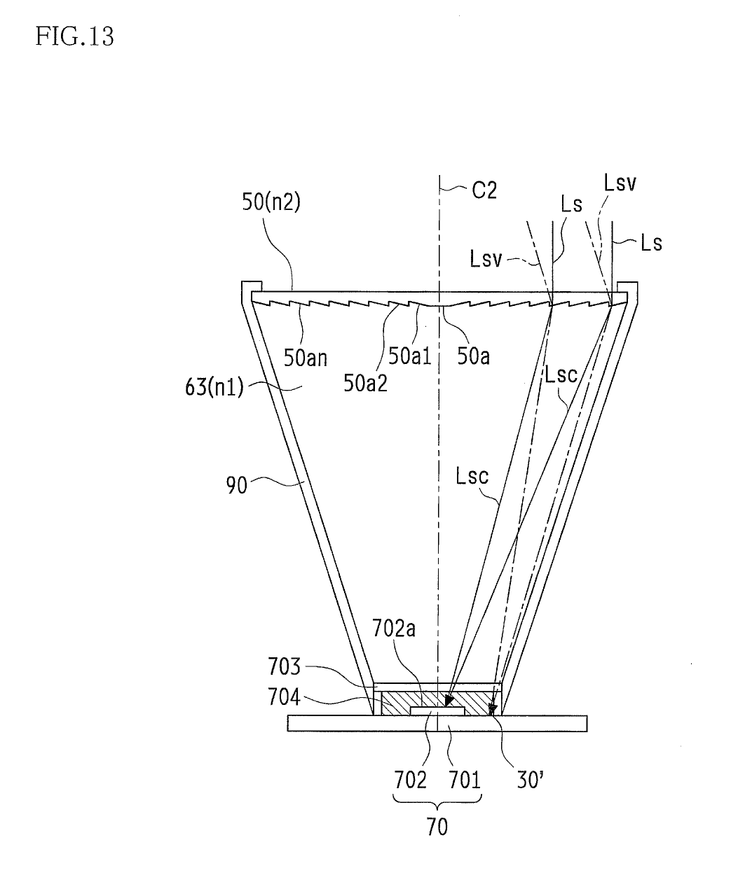

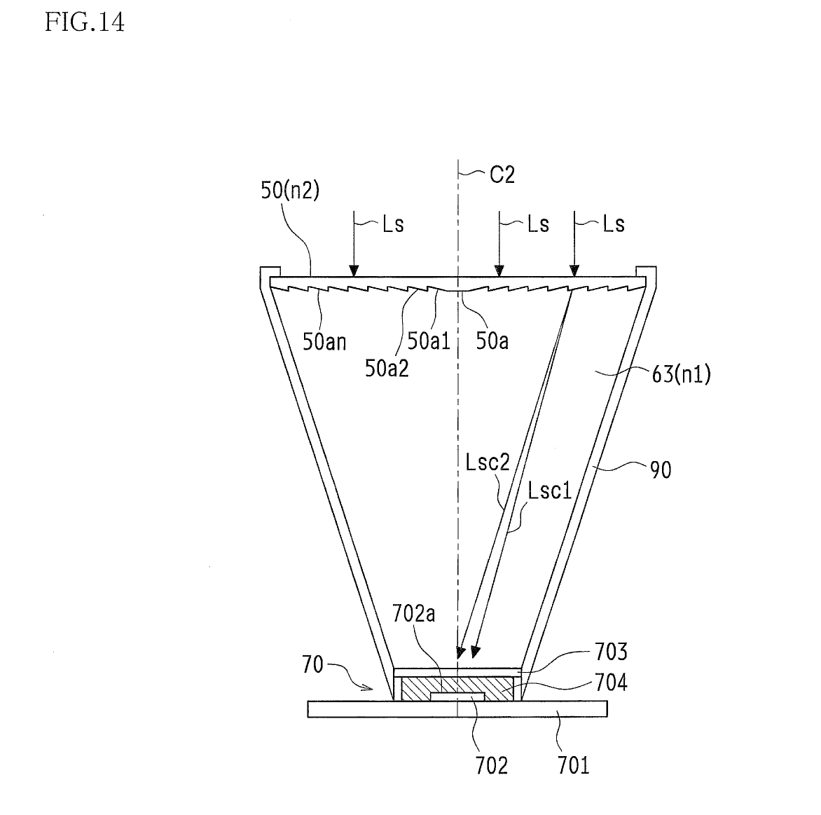

The optical member 13 is configured so as to include an optical refraction portion 131 having a curved face for refracting and concentrating sunlight Ls, a concentrated light emission portion 133 that is arranged in close contact with the sealing portion 12 in order to emit the sunlight Ls concentrated by the optical refraction portion 131 toward the solar cell element 101, and an optical base portion 132 arranged between the optical refraction portion 131 and the concentrated light emission portion 133. Also, the optical member 13 has an integrated structure in which there is no intermediate air layer from the optical refraction portion 131 to the concentrated light emission portion 133 with the optical base portion 132 therebetween. In other words, the intermediate air layer 63 in the conventional technology shown in FIGS. 13 and 14 is replaced with the optical base portion 132 in the present invention. The optical member 13 having such a structure is constituted using, for example, a transmissive glass material or at least one resin material from among silicone resin, acrylic resin, fluorine resin, and epoxy resin, and is an optical system that ensures heat resistance and moisture resistance.

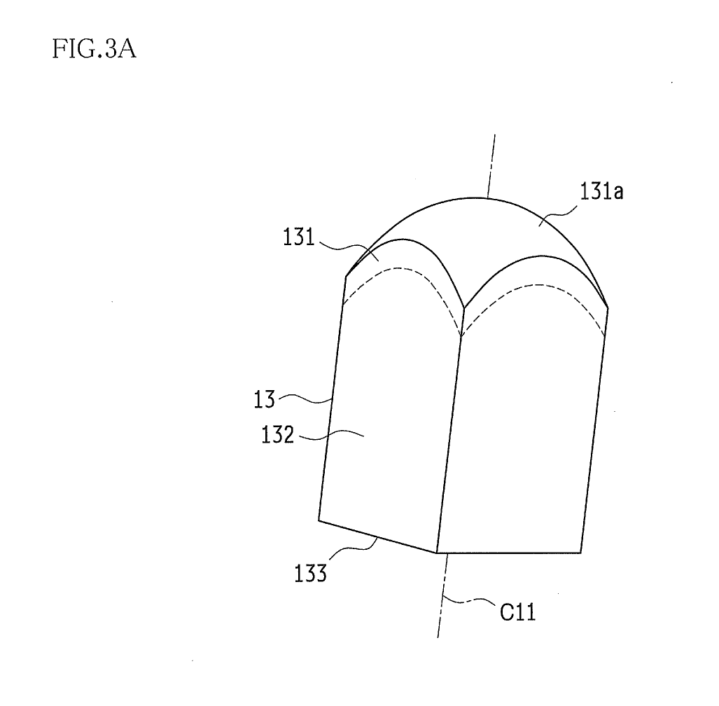

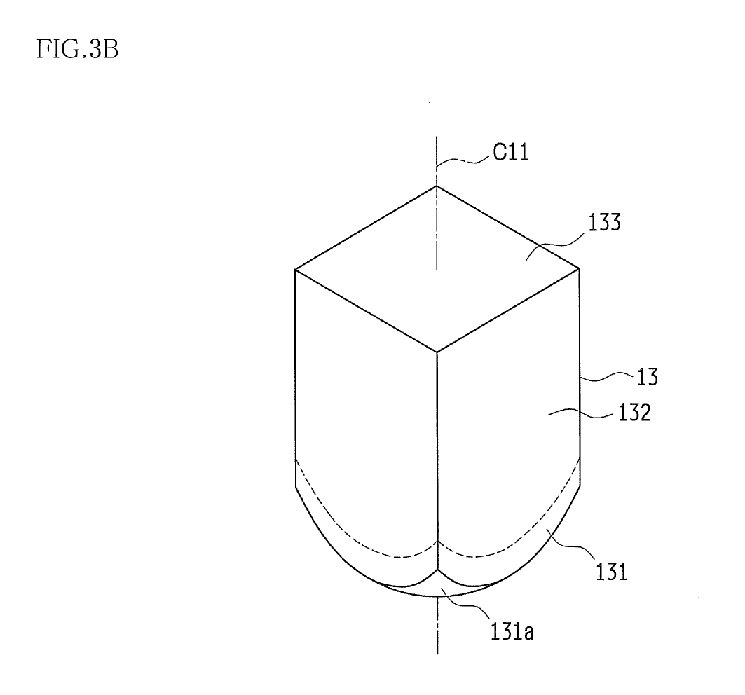

FIG. 3A is a perspective view of the optical member 13 as viewed obliquely from above, and FIG. 3B is a perspective view of the optical member 13 as viewed from the bottom face side.

The optical base portion 132 is shaped as a prism with the square-shaped concentrated light exit portion 133 as the bottom face, and the optical refraction portion 131 is formed so as to have the same outer peripheral shape and outer peripheral size as the optical base portion 132.

The optical refraction portion 131 shaped in this way is formed so as to be dome-shaped overall with a predetermined thickness, and the curvature of the upper surface side (sunlight entrance face 131a (see FIG. 2)) and the bottom face side (sunlight exit face 131b (see FIG. 2)) are set so as to minimize the spot area of a concentrated light focal point group 30 formed by the concentrated sunlight Lsc on a light receiving face 101a of the solar cell element 101. Note that the shape of the surface of the optical refraction portion 131 may be either a circle or an ellipse. Similarly, the upper face side of the optical base portion 132 (i.e., an entrance face 132a that is in contact with the bottom face of the optical refraction portion 131) also has the same dome shape, and the curvature is the same as the curvature of the optical refraction portion 131. In other words, since the exit face 131b of the optical refraction portion 131 and the entrance face 132a of the optical base portion 132 have the same dome shape with the same curvature, it is possible to obtain an integrated structure in which the optical base portion 132 and the optical refraction portion 131 are combined closely so as to have no air layer between them.

Note that the refractive index of the material constituting the optical member 13, the total length of the optical base portion 132, and the curvature of the dome shape are correlated to each other, and therefore they need to be respectively designed so as to minimize the spot area of the concentrated light focal point group 30 on the light receiving face 101a of the solar cell element 101. For example, in the case of using a glass material with a refractive index of 1.5 to 1.7 as the material constituting the optical member 13, it is preferable that the dimensions of the various portions of the optical member 13 are set such that the ratio of a width W1 of the concentrated light emission portion 133 (length of one side of the concentrated light exit portion shaped as a square) to a length H2 from the top portion of the optical refraction portion 131 to the concentrated light emission portion 133 is in the range of 1:1.5 to 1:3.

The sealing portion 12 is formed by transparent insulating resin (e.g., at least one resin material from among silicone resin, acrylic resin, fluorine resin, and epoxy resin) that fills the space between the solar cell element 101 and the optical member 13, and is configured such that the light receiving face 101a of the solar cell element 101 is irradiated with the concentrated sunlight Lsc. Note that it is desirable that the insulating resin that is used in the sealing portion 12 has an internal transmissivity of 99.9% or more with respect to the wavelength band of 300 nm to 2000 nm. Also, the smaller the difference in refractive index is from the refractive index of the material forming the optical member 13, the better, and a transparent silicone resin having a refractive index of approximately 1.4, for example, can be favorably used. Also, by sealing the concentrated light emission portion 133 and the solar cell element 101 by adhesion using the sealing portion 12 (i.e., adhering the concentrated light emission portion 133 and the solar cell element 101 together with the insulating resin (adhesive material)), it is possible to prevent the entrance of moisture and water into the solar cell element 101, thus enabling improving the reliability and weather resistance.

In Embodiment 1, the optical member 13 is configured so as to always directly face the sun through the operation of a tracking mechanism (not shown) for tracking the sun. Accordingly, the sunlight Ls is always incident in the perpendicular direction along a centerline C1 (see FIG. 2) of the entrance face 131a of the optical member 13. The sunlight Lsc that is incident on the optical member 13 is refracted by the dome-shaped optical refraction portion 131, passes through the interior of the optical base portion 132, and is emitted onto the light receiving face 101a of the solar cell element 101.

In this way, the sunlight Ls is concentrated on the light receiving face 101a of the solar cell element 101 by the tracking mechanism, but there are cases where, for example, the spot position of the concentrated light focal point group 30 is misaligned due to several degrees of tracking error in the tracking mechanism.

In this case, with the concentrated solar cell having the conventional configuration shown in FIG. 13, when the sunlight Lsv that deviates somewhat from the perpendicular direction due to several degrees of sun tracking error, it is possible for the spot position of the focal point group 30′ for light concentrated by the concentrating lens 50 to deviate from the light receiving face 702a of the solar cell element 702, and for the receiver substrate 701 to be directly irradiated by the concentrated light focal point group 30′.

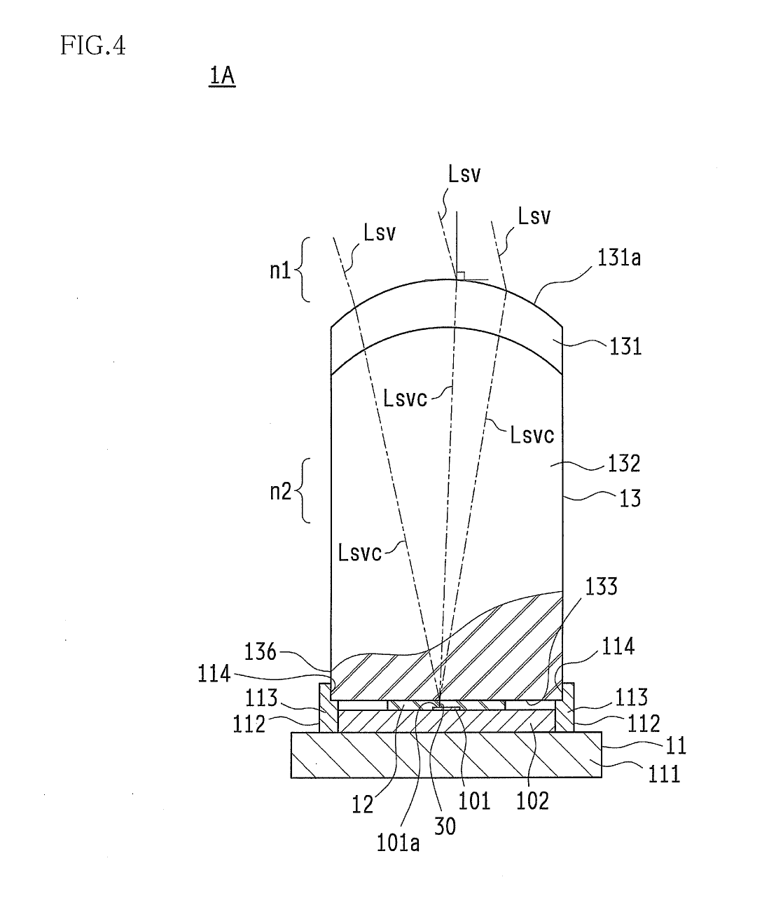

In contrast, the concentrated solar cell 1A of Embodiment 1 does not have the intermediate air layer 63 (see FIGS. 13 and 14) that exists in conventional concentrated solar cells, and therefore as shown in FIG. 4, the sunlight Lsv that is incident on the optical member 13 somewhat deviated from the perpendicular direction also passes through the interior of the optical base portion 132 and is guided onto the light receiving face 101a of the solar cell element 101. Here, the sunlight Lsvc concentrated by the dome-shaped optical refraction portion 131 has a low angle of refraction since it is concentrated by undergoing refraction one time at the entrance face 131a, which is the boundary portion between the air layer, which is a low refractive index portion n1, and the optical refraction portion 131, which is a high refractive index portion n2. As a result, the amount of misalignment of the spot position of the concentrated light focal point group 30 occurring due to several degrees of tracking error is also lower than the amount of misalignment of the spot position of the concentrated light focal point group 30 in conventional concentrated solar cells, and therefore it is possible to improve the output stability, reliability, and weather resistance of the concentrated solar cell.

In this case, in Embodiment 1, the solar cell element 101 is designed so as to be larger than the spot size of the concentrated light focal point group 30. Specifically, it is configured such that the spot position of the concentrated light focal point group 30 is located within the light receiving face 101a of the solar cell element 101. Accordingly, even if the sunlight Lsv somewhat deviates from the perpendicular direction due to several degrees of tracking error, the spot position of the emitted concentrated light focal point group 30 does not deviate from the light receiving face 101a of the solar cell element 101.

Accordingly, with the concentrated solar cell 1A of Embodiment 1 that uses the optical member 13, there is no reduction in output even if several degrees of tracking error arises. Since the receiver substrate 102 is not irradiated by the concentrated light focal point group 30, it is possible to prevent the members arranged on the surface of the receiver substrate 102 from being burned, and to obtain a high-efficiency and high-quality concentrated solar cell.

Also, the optical member 13 has an integrated structure in which there is no intermediate air layer from the optical refraction portion 131 to the concentrated light emission portion 133 with the optical base portion 132 therebetween, and the optical base portion 132 is shaped as a prism with the square-shaped concentrated light exit portion 133 as the bottom face. According to this structure, an optical outer diameter portion 136 of the optical base portion 132 in the periphery of the concentrated light emission portion 133 does not serve as an optical path for the sunlight Lsc that is refracted and concentrated by the optical refraction portion 131. In other words, the outer peripheral faces of the optical base portion 132 are arranged outside the optical path of the concentrated sunlight Lsc. This enables the portion of the optical base portion 132 in the periphery of the concentrated light emission portion 133 to be used as a support portion.

With the typical concentrated solar cell shown in FIGS. 13 and 14, the amount of sunlight Ls that directly contributes to output corresponds to the surface area of the concentrating lens 50, and the surface area of the concentrating lens 50 needs to be made as large as possible. In other words, eliminating portions that obstruct incident sunlight Ls as much as possible in the concentrating lens 50 leads to an increase in efficiency.

Also, with the typical concentrated solar cell shown in FIGS. 13 and 14, aligning the center of the concentrating lens 50 and the center of the solar cell element 702 requires special marking called “alignment marks” that are not lens portions of the concentrating lens 50, and a module frame 90, which is a support portion for supporting the concentrating lens 50 and the solar cell substrate (solar cell 70), and the module frame 90 in particular substantially decreases the surface area of the concentrating lens 50, thus leading to a reduction in output.

In contrast, with the optical member 13 of Embodiment 1, the optical outer diameter portion 136 of the optical base portion 132 is supported by the support member 11 on which the solar cell substrate 10 is placed, thus allowing the sunlight Ls to be incident on the optical refraction portion 131 without loss.

As shown in FIGS. 1 and 2, the support member 11 includes a support substrate 111 that is square-shaped in a plan view and slightly larger than the receiver substrate 102, and four support parts 112 for respectively supporting the side faces of the optical outer diameter portion 136 of the optical base portion 132 are provided upright on the support substrate 111.

The support parts 112 are arranged at positions opposing the respective side faces of the optical outer diameter portion 136, and each include a base part 113 provided so as to stand perpendicular on the support substrate 111, and a support claw 114 formed on the corner portion on the upper end of the base part 113.

The support claw 114 is formed in the shape of a cutout “L”, in a side view, that opens toward a substrate center P of the support substrate 111, and is constituted by a bottom face support portion 114a that supports the outer peripheral portion of the concentrated light emission portion 133, which is the bottom face of the optical outer diameter portion 136, from below, and a side face support portion 114b that supports a side face of the lower portion of the optical outer diameter portion 136 from the horizontal direction. Also, the support claws 114 are formed such that a distance L1 between the side face support portions 114b of a pair of support parts 112 arranged so as to oppose each other across the substrate center P is substantially the same as a width W1 between opposing side faces of the optical outer diameter portion 136 (width of the concentrated light emission portion 133) (i.e., L1≈W1), and the optical outer diameter portion 136 is supported so as to not be horizontally misaligned when fitted in between the side face support portions 114b of the opposing support pieces 114.

Also, the support claws 114 are formed such that a distance L3 between the base parts 113 of a pair of support parts 112 arranged so as to oppose each other across the substrate center P is substantially the same as a horizontal width W3 of the receiver substrate 102 (L3≈W3). Accordingly, when the receiver substrate 102 is to be placed on the support substrate 111, merely dropping the receiver substrate 102 into the space between the four support pieces 114 so as to be fitted therein enables the receiver substrate 102 to be placed at a precise position on the support substrate 111. In other words, in the present invention, the support parts 112 additionally function as positioning members for placing the receiver substrate 102 at a precise position on the support substrate 111.

Accordingly, after the receiver substrate 102 is placed on the support substrate 111, by merely placing the optical outer diameter portion 136 of the optical member 13 in between the support claws 114 of the support parts 112 so as to be supported by them, it is possible to precisely align the center of the solar cell element 101, which is mounted in the central portion of the receiver substrate 102, and the center of the concentrated light emission portion 133 of the optical member 13. In other words, by merely placing the receiver substrate 102 on the support substrate 111 and then placing the optical outer diameter portion 136 of the optical member 13 in between the support pieces 114 of the support member 11, it is possible to precisely position the center of the solar cell element 101 and the center of the optical member 13, thus enabling easily manufacturing the high-quality and highly reliable concentrated solar cell 1A.

Also, the support pieces 114 are formed so that a height H1 from the surface of the support substrate 111 to the bottom face support portion 114a is the same for all of the support pieces 114. Accordingly, by merely placing the optical outer diameter portion 136 of the optical member 13 in between the four support pieces 114 of the support member 11 so as to be supported by them, it is possible to arrange the concentrated light emission portion 133, which is the bottom face of the optical member 13, and the upper face of the receiver substrate 102 on which the solar cell element 101 is mounted (more specifically, the light receiving face 101a of the solar cell element 101) so as to be parallel to each other.

Also, the height H1 is set to a height according to which the spot position of the concentrated light focal point group 30 is located on the light receiving face 101a of the solar cell element 101 when the optical outer diameter portion 136 of the optical member 13 is placed in between the support pieces 114 of the support member 11 so as to be supported by them, and according to which the concentrated light emission portion 133 of the optical member 13 comes into contact with the sealing portion 12 for sealing the solar cell element 101.

Note that since the support member 11 is used as a positioning member for aligning the center of the solar cell element 101 and the center of the optical member 13 as described above, it is preferably formed by a method that enables manufacturing with relatively favorable dimensional precision, such as metal milling or injection molding using a metal material. Note that in order to reduce the weight and cost of the concentrated solar cell, the optical member 13 may be a resin molded article or a glass molded article.

Also, as will be described in connection with the later-described manufacturing method, the receiver substrate 102 is fixed onto the support substrate 111 by an adhesive material, solder welding, screw fixing, or the like. Also, the concentrated light emission portion 133 of the optical member 13 placed in between the support pieces 114 of the support member 11 is adhered and fixed to the sealing portion 12 by melting and then hardening the portion of the sealing portion 12 that comes into contact with it. Thus, a concentrated solar cell having an integrated structure is manufactured. Note that in order to further increase the strength of the integrated structure, the support pieces 114 of the support member 11 and the optical outer diameter portion 136 of the optical member 13 placed therebetween may also be adhered and fixed to each other using an adhesive material or the like.

Also, since fixing the receiver substrate 102 onto the support substrate 111 enables heat generated by the receiver substrate 102 to be dissipated via the support substrate 111, it is possible to raise the heat dissipation performance of the concentrated solar cell.

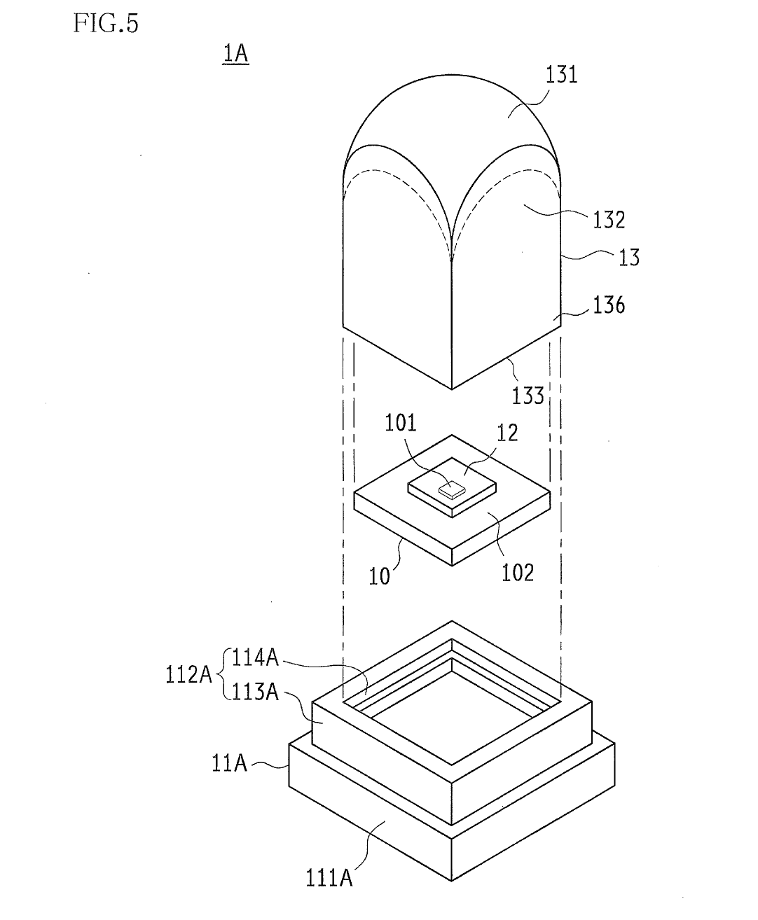

FIG. 5 shows a support member 11A according to another working example.

Whereas the support member 11 shown in FIG. 1 is constituted by the four support parts 112 that support the optical outer diameter portion 136 of the optical base portion 132, the support member 11A shown in FIG. 5 has a support part 112A that is constituted by a base part 113A and a support claw 114A that are formed in the shape of a square in a plan view so as to conform to the outer peripheral shape of the optical outer diameter portion 136. Specifically, in this configuration, the base part 113A is formed in the shape of a four-cornered frame with an open upper portion, and the support claw 114A, which has an L-shaped cross-section, is formed in the shape of a ring that conforms to the inner peripheral wall side of the upper face portion of the frame. This configuration enables forming a more robust support member 11A, and also enables more stably supporting the optical member 13.

The concentrated solar cell 1A of Embodiment 1 enables eliminating the intermediate air layer that exists in the structure of conventional concentrated solar cells. Specifically, it is possible to eliminate a reduction in performance caused by light intensity reflection that occurs as a result of a large difference between refractive indices caused by the existence of an intermediate air layer, thus enabling improving the output of the concentrated solar cell.

### Embodiment 2

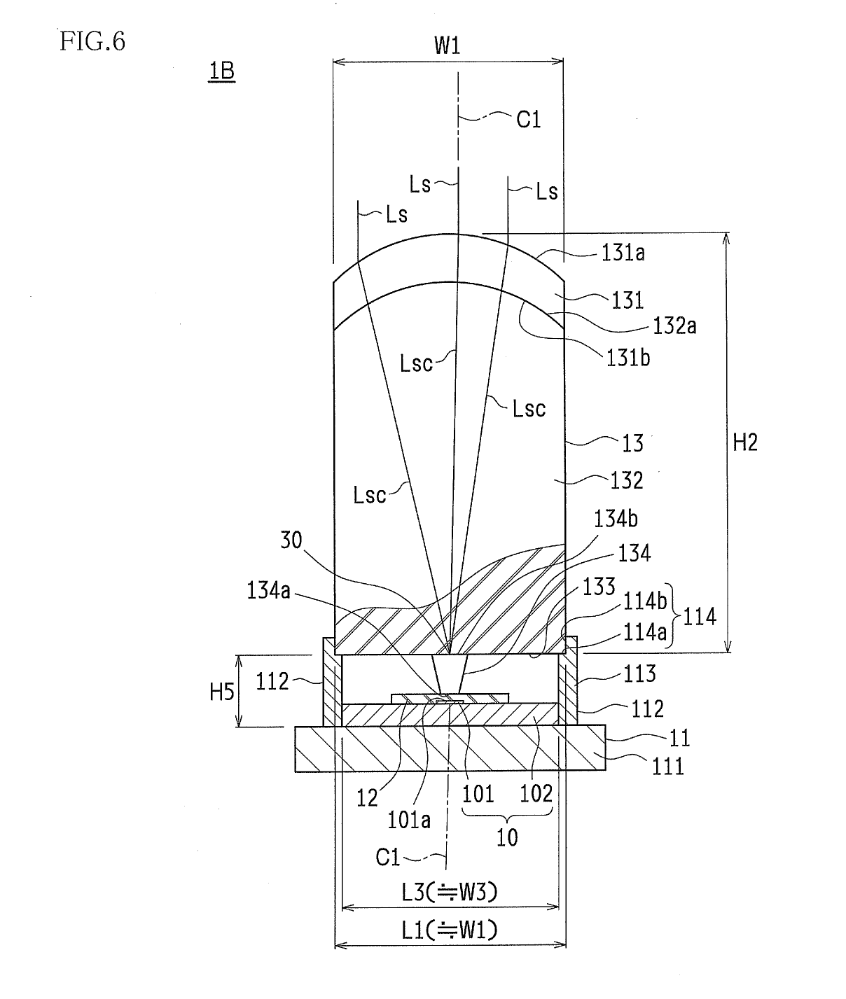

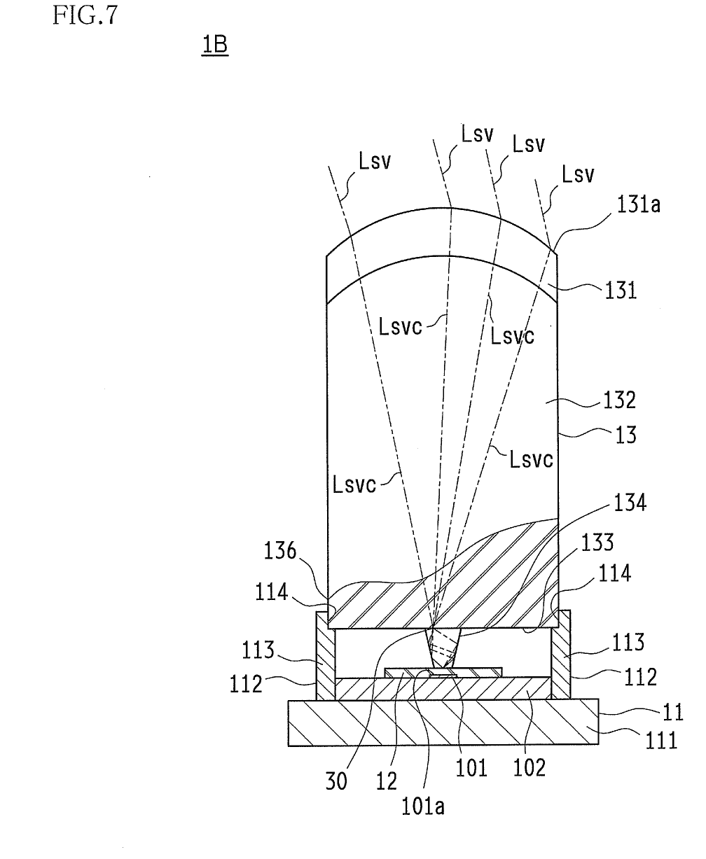

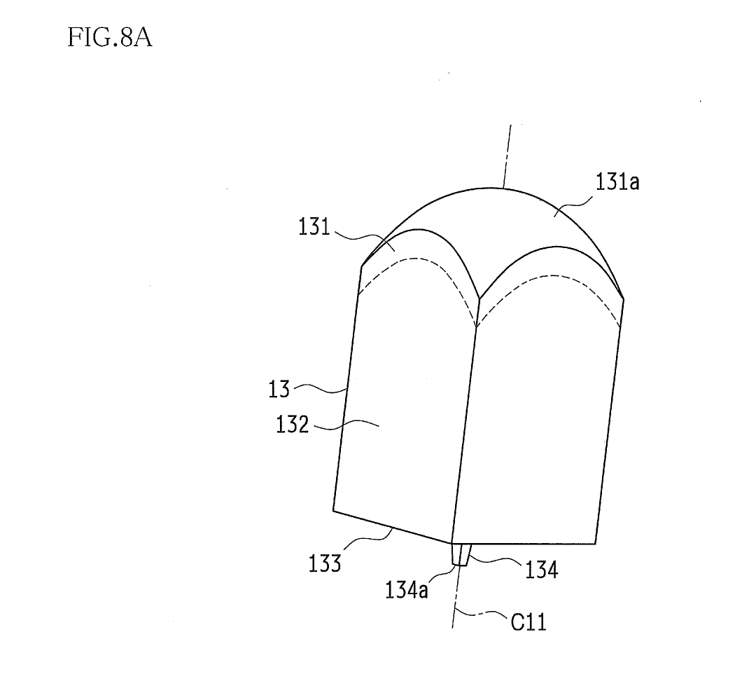

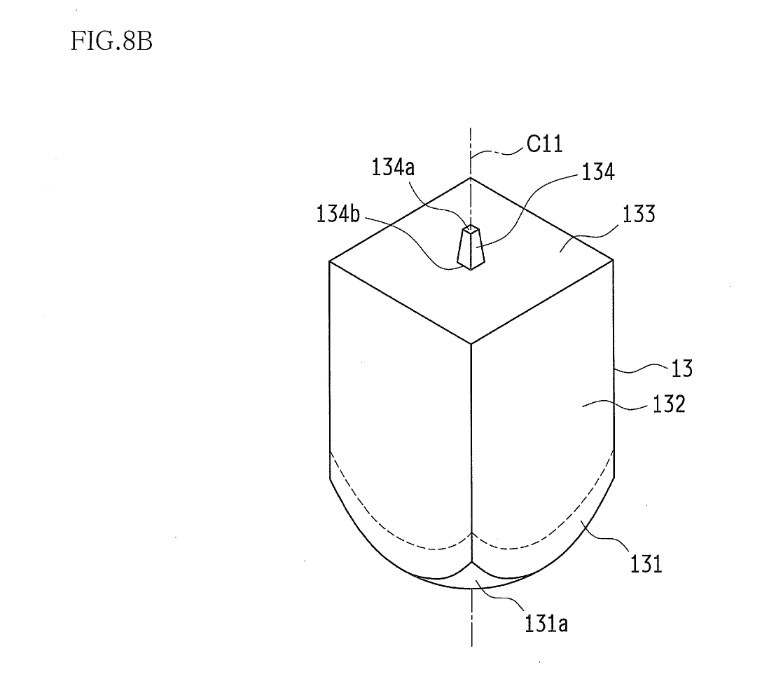

FIGS. 6 and 7 are side views showing a partially fractured view of a concentrated solar cell 1B according to Embodiment 2. FIG. 8A is a perspective view of the optical member 13 according to Embodiment 2 as viewed from above, and FIG. 8B is a perspective view of the same as viewed from the bottom face side.

In the concentrated solar cell 1B of Embodiment 2, a columnar optical portion 134 is integrally formed on the concentrated light emission portion 133 of the optical member 13 in the concentrated solar cell 1A of Embodiment 1. The columnar optical portion 134 is integrally formed on a portion of the concentrated light exit portion 133 where the concentrated light focal point group 30 is located, that is to say, a location in the central portion (centerline C1 of the optical base portion 132) of the concentrated light exit portion 133.

This configuration enables the optical member 13 to have the effects of the optical member 13 described in Embodiment 1 as well advantages of the columnar optical portion 134.

Note that with the exception that a height H5 from the surface of the support substrate 111 of the support portion 11 to the bottom face support portion 114b of the support claw 114 is higher by an amount corresponding to the height of the columnar optical portion 134, the other configurations are the same as those in Embodiment 1, and therefore the identical members will be denoted by the same reference signs, descriptions will not be given for these identical members, and only portions related to the columnar optical portion 134 will be described below.

The columnar optical portion 134 is formed as a protrusion that extends perpendicularly downward from the central portion of the concentrated light emission portion 133, and is arranged such that a tip portion 134a is in close contact with the sealing portion 12. Similarly to the sealing portion 12 of the concentrated solar cell 1A of Embodiment 1, the sealing portion 12 is formed by transparent insulating resin (e.g., at least one resin material from among silicone resin, acrylic resin, fluorine resin, and epoxy resin) that fills the space between the solar cell element 101 and the tip portion 134a of the columnar optical portion 134. In other words, the solar cell element 101 and the tip portion 134a of the columnar optical portion 134 are adhered together with the insulating resin (adhesive material).

As shown in FIGS. 8A and 8B, the columnar optical portion 134 is formed in the shape of a prism having a square cross-sectional face, and is provided so as to gradually decrease in cross-sectional size from an upper end portion (upper end face) 134b on the concentrated light emission portion 133 side toward the tip portion (emission face) 134a. More specifically, the side faces of the columnar optical portion 134 have an arbitrary angle of inclination θ from approximately 0 degrees to 20 degrees relative to a centerline C11 of the columnar optical portion 134. In other words, the columnar optical portion 134 gradually becomes wider moving upward from the emission face 134a at an angle equal to the angle of inclination θ (0 degrees<θ≦20 degrees), and therefore the upper end face 134b of the columnar optical portion 134 has a larger surface area than that of the emission face 134a of the columnar optical portion 134 and furthermore the light receiving face 101a of the solar cell element 101. Also, the columnar optical portion 134 is formed with a size according to which the emission face 134a (tip portion 134a) is located within the light receiving face 101a of the solar cell element 101.

According to this configuration, the concentrated light (sunlight Lsc) that is incident on the columnar optical portion 134 is guided to the light receiving face 101a of the solar cell element 101 due to repeatedly undergoing total reflection at the side faces of the columnar optical portion 134, thus eliminating chromatic aberration on the light receiving face 101a of the solar cell element 101 and making it possible to also eliminate fluctuation in the intensity of the sunlight Lsc. This makes it possible to further improve the output of the solar cell.

Also, the columnar optical portion 134 is provided such that the spot position of the concentrated light focal point group 30 of the sunlight concentrated by the optical member 13 is positioned within the upper end face 134b. In other words, the upper end face 134b of the columnar optical portion 134 is designed so as to be larger than the spot size of the concentrated light focal point group 30. Accordingly, even if there is sunlight Lsv that is incident somewhat deviated from the perpendicular direction due to several degrees of tracking error as shown in FIG. 7, or misalignment occurs when the optical member 13 is assembled, the sunlight Lsv is incident on the columnar optical portion 134, repeatedly undergoes total reflection at the side faces of the columnar optical portion 134, and is then entirely emitted on the light receiving face 101a of the solar cell element 101, thus making it possible to obtain the high-quality and high-efficiency concentrated solar cell 1B.

In this way, according to Embodiment 2, using the optical member 13 having the columnar optical portion 134 obtains the effects described in Embodiment 1 as well as makes it possible to eliminate chromatic aberration and intensity fluctuation of the sunlight Ls, thus enabling obtaining the concentrated solar cell 1B having even higher efficiency.

The following describes a method for manufacturing a concentrated solar cell having the above-described configurations.

Step 1: First, the optical member 13 is prepared (optical member preparation step).

The optical member 13 that is to be prepared is preferably manufactured using optical glass having favorable transmissivity in view of weather resistance and reliability. In order to form the optical refraction portion 131 so as to allow the sunlight Ls to efficiently be incident on the solar cell element 101, the optical member 13 is manufactured by molding or milling. Note that there is no limitation to these methods. It should also be noted that instead of the optical member 13 having the columnar optical portion 134 being formed all at once by molding or milling, a configuration is possible in which the optical refraction portion 131 and the optical base portion 132 are formed by molding or milling and then integrated with the columnar optical portion 134 by adhesion using transparent resin or an optical contact.

Also, in consideration of weight reduction and cost reduction, the optical member 13 can be manufactured using silicone resin, acrylic resin, plastic, or the like.

Step 2: Next, the solar cell element 101 is mounted on the receiver substrate 102 (receiver substrate preparation step).

The receiver substrate 102 is a substrate obtained by connecting electrodes (not shown) of the solar cell element 101 to a base foundation such as an aluminum plate or a copper plate, which additionally functions as an electrode, via an appropriate insulating layer made of a ceramic, glass, or the like. The solar cell element 101 is precisely arranged on the base foundation and then adhered and fixed thereto using solder, electrode paste, or the like.

Note that due to demand for high efficiency and practical utility, it is desirable for the solar cell element 101 applied to the concentrated solar cell to be a triple junction solar cell element constituted by InGaP/GaAs/Ge, a solar cell element constituted by AlGaAs/Si, or a monolithic multi-junction solar cell element.

Step 3: Next, the receiver substrate 102 is placed on the support member 11 (receiver substrate mounting step).

As described above, the base parts 113, 113A of the support member 11 also function as positioning members for precisely placing the receiver substrate 102 on the support substrate 111, 111A, and therefore the receiver substrate 102 can be precisely placed merely dropping it into the space between the base parts 113, 113A so as to be fitted therein. Thereafter, the receiver substrate 102 is fixed onto the support substrate 111, 111A by, for example, adhesion using solder or a resin such as an adhesive material, for example, or mechanical holding using screw fixing or the like.

Step 4: Next, the sealing portion 12 is formed on the receiver substrate 102 (on the upper portion of the solar cell element 101) (sealing step).

It is desirable for the sealing portion 12 to be formed from silicone resin, acrylic resin, an adhesive material, or the like that have favorable transmissivity and favorable adhesion to the optical member 13. Since resin and the like have fluidity, it is preferable that a metal frame or plastic frame is formed, the metal frame or plastic frame is placed on the receiver substrate 102 so as to surround the solar cell element 101, and then the frame is filled with a predetermined amount of resin.

Step 5: Next, the optical member 13 is mounted on the support member 11 (optical member mounting step).

After the receiver substrate 102 is placed on the support substrate 111, 111A, the optical member 13 is placed on the support member 11 by placing the optical outer diameter portion 136 of the optical member 13 in the space between the support claws 114, 114A of the support part 112, 112A from above. This placement alone enables precisely aligning the center of the solar cell element 101 of the receiver substrate 102 and the center of the concentrated light emission portion 133 of the optical member 13.

Step 6: Next, the optical member 13 and the sealing portion 12 are adhered together (sealing portion integrated optical system adhesion step).

While the optical member 13 is placed on the support member 11, the concentrated light emission portion 133 of the optical member 13 or the emission face 134a of the columnar optical portion 134 is in contact with the sealing portion 12. Also, the resin used for the sealing portion 12 is generally a thermal-curing or air-setting resin. Accordingly, by curing the resin according to its specification, the sealing portion 12 can be adhered to the concentrated light emission portion 133 of the optical member 13 or the emission face 134a of the columnar optical portion 134 in contact with the resin.

This enables manufacturing the concentrated solar cell 1A, 1B in which the solar cell substrate 10, the support member 11, the sealing portion 12, and the optical member 13 are integrated.

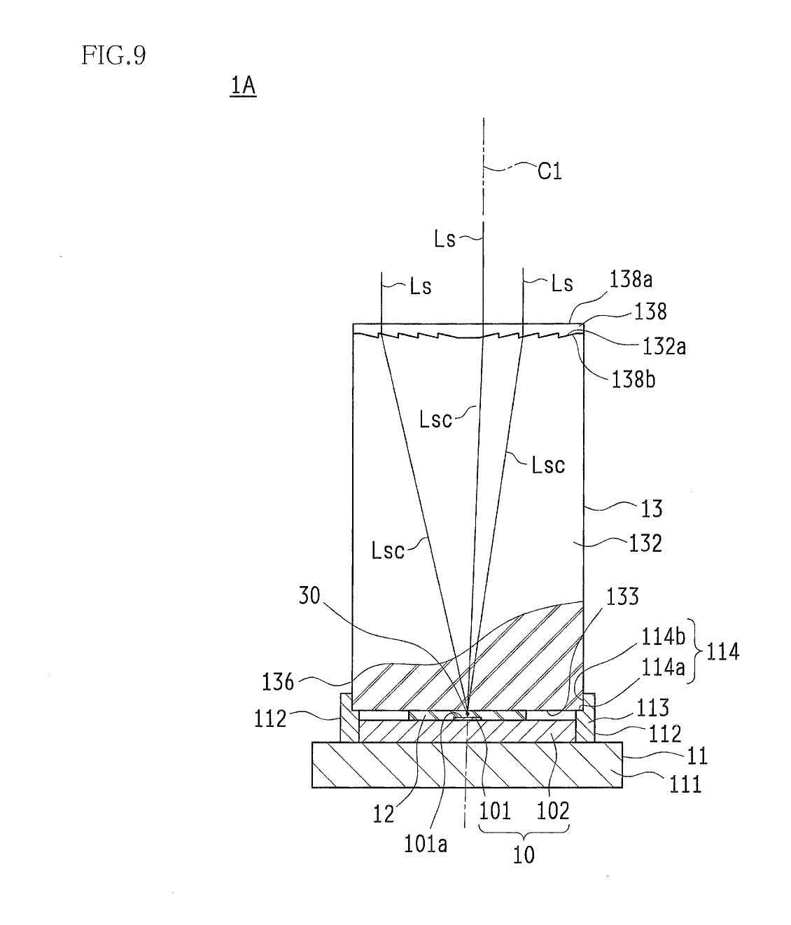

Note that although the optical refraction portion 131 is dome-shaped in Embodiments 1 and 2, it may be a Fresnel lens-shaped optical refraction portion 138 as shown in FIG. 9. In this case, the entrance face 132a of the optical base portion 132 is formed so as to conform to the shape of a lens face 138b, which is the lower face of the optical refraction portion 138.

### Embodiment 3

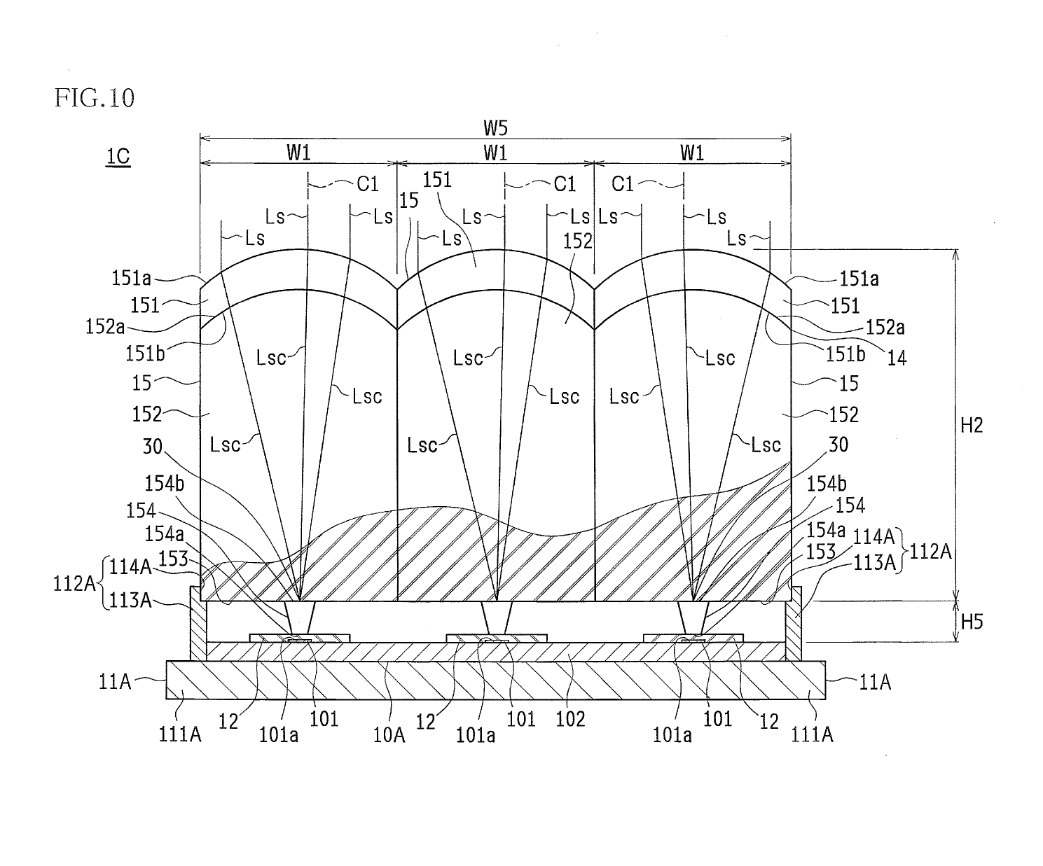

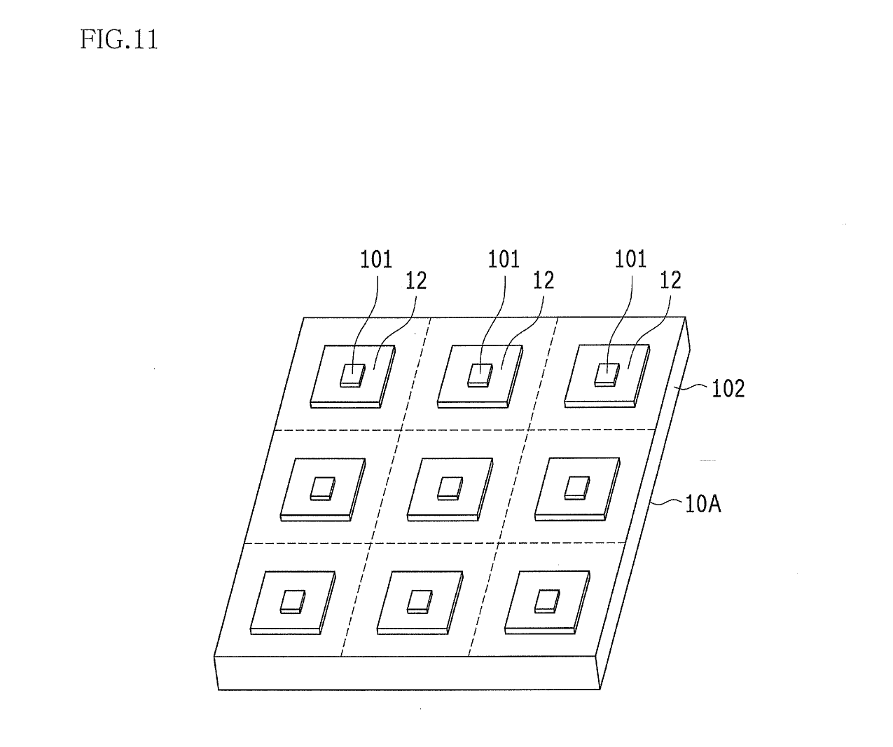

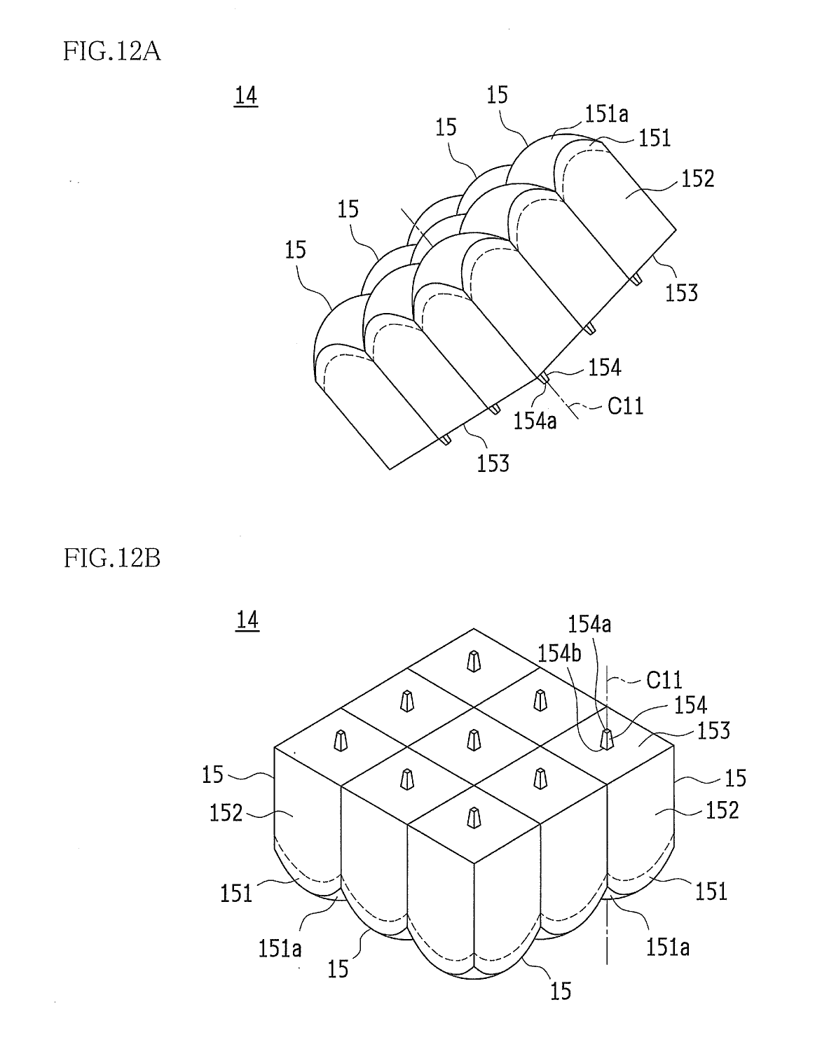

FIG. 10 is a side view showing a partially fractured view of a concentrated solar cell 1C according to Embodiment 3. FIG. 11 is a perspective view of the arrangement of solar cell elements 101 on a receiver substrate (element substrate) 102 in the concentrated solar cell 1C according to Embodiment 3. FIG. 12A is a perspective view of an optical member 14 according to Embodiment 3 as viewed obliquely from above. FIG. 12B is a perspective view of the optical member 14 according to Embodiment 3 as viewed from the bottom face side.

The concentrated solar cell 1C according to Embodiment 3 is configured such that multiple solar cell elements 101 are mounted on the receiver substrate 102, and the optical member 14 serving as the optical member of the concentrated solar cell 1C has multiple optical portions 15, each having a configuration similar to that of the optical member 13 of Embodiment 2 described above, in correspondence with the solar cell elements 101. For this reason, the concentrated solar cell 1C of Embodiment 3 achieves effects similar to those of the concentrated solar cell 1B of Embodiment 2.

Specifically, the concentrated solar cell 1C of Embodiment 3 is configured so as to include a solar cell substrate 10A obtained by mounting multiple (specifically, nine) solar cell elements 101 on the receiver substrate (element substrate) 102, multiple sealing portions 12 provided on the receiver substrate 102 so as to individually cover the respective solar cell elements 101, the integrated-structure optical member 14 that is provided on the sealing portions 12 and concentrates sunlight on the solar cell elements 101, and a support member 11A that integrally supports the receiver substrate 102 and the optical member 14.

As shown in FIG. 11, the solar cell elements 101 are arranged in an array on the receiver substrate 102 with predetermined gaps in the row direction and the column direction. These solar cell elements 101 each have a configuration similar to the solar cell element 101 of the concentrated solar cells 1A and 1B in Embodiments 1 and 2 described above.

Also, the receiver substrate 102 is formed with a size that allows the solar cell elements 101 to be mounted, and has a configuration similar to that of the receiver substrate 102 of the concentrated solar cells 1A and 1B of Embodiments 1 and 2 described above, with the exception that wiring is formed in correspondence with the respective solar cell elements 101 mounted on the receiver substrate 102.

As shown in FIGS. 12A and 12B, the optical member 14 has a structure in which multiple (nine) optical portions 15 respectively corresponding to the solar cell elements 101 mounted on the receiver substrate 102 are arranged in a continuous array without gaps in the row direction and the column direction.

The optical portions 15 of the optical member 14 each have a configuration similar to the optical member 13 of Embodiment 2 described above. Specifically, each optical portion 15 is configured so as to include an optical refraction portion 151 having a curved face for refracting and concentrating sunlight Ls, a concentrated light emission portion 153 that is arranged in close contact with the sealing portion 12 in order to emit the sunlight Ls concentrated by the optical refraction portion 151 toward one solar cell element 101, and an optical base portion 152 arranged between the optical refraction portion 151 and the concentrated light emission portion 153. Also, the optical portion 15 has an integrated structure in which there is no intermediate air layer from the optical refraction portion 151 to the concentrated light emission portion 153 with the optical base portion 152 therebetween. The optical member 14 having these optical portions 15 is constituted using, for example, a transmissive glass material or at least one resin material from among silicone resin, acrylic resin, fluorine resin, and epoxy resin, and is an optical system that ensures heat resistance and moisture resistance.

The optical base portion 152 is shaped as a prism with the square-shaped concentrated light exit portion 153 as the bottom face, and the optical refraction portion 151 is formed so as to have the same outer peripheral shape and outer peripheral size as the optical base portion 152.

The optical refraction portion 151 shaped in this way is formed so as to be dome-shaped overall with a predetermined thickness, and the curvature of the upper surface side (sunlight entrance face 151a (see FIG. 10)) and the bottom face side (sunlight exit face 151b (see FIG. 10)) are set so as to minimize the spot area of a concentrated light focal point group 30 formed by the concentrated sunlight Lsc on the light receiving face 101a of the solar cell element 101. Note that the shape of the surface of the optical refraction portion 151 may be either a circle or an ellipse. Similarly, the upper face side of the optical base portion 152 (i.e., an entrance face 152a that is in contact with the bottom face of the optical refraction portion 151) also has the same dome shape, and the curvature is the same as the curvature of the optical refraction portion 151. In other words, since the exit face 151b of the optical refraction portion 151 and the entrance face 152a of the optical base portion 152 have the same dome shape with the same curvature, it is possible to obtain an integrated structure in which the optical base portion 152 and the optical refraction portion 151 are combined closely so as to have no air layer between them.

Note that the refractive index of the material constituting the optical member 14, the total length of the optical base portion 152, and the curvature of the dome shape are correlated to each other, and therefore they need to be respectively designed so as to minimize the spot area of the concentrated light focal point group 30 on the light receiving face 101a of the solar cell element 101. For example, in the case of using a glass material with a refractive index of 1.5 to 1.7 as the material constituting the optical member 14, it is preferable that the dimensions of the various portions of the optical member 14 are set such that the ratio of a width W1 of the concentrated light emission portion 153 (length of one side of the concentrated light exit portion shaped as a square) to a length H2 from the top portion of the optical refraction portion 151 to the concentrated light emission portion 153 is in the range of 1:1.5 to 1:3.

Also, a columnar optical portion 154 is integrally formed on the concentrated light emission portion 153 of each of the optical portions 15. The columnar optical portion 154 is integrally formed on a portion of the concentrated light exit portion 153 where the concentrated light focal point group 30 is located, that is to say, a location in the central portion (centerline C1 of the optical base portion 152) of the concentrated light exit portion 153. This columnar optical portion 154 is formed as a protrusion that extends perpendicularly downward from the central portion of the concentrated light emission portion 153, and is arranged such that a tip portion 154a is in close contact with the sealing portion 12.

As shown in FIGS. 12A and 12B, the columnar optical portion 154 is formed in the shape of a prism having a square cross-sectional face, and is provided so as to gradually decrease in cross-sectional size from an upper end portion (upper end face) 154b on the concentrated light emission portion 153 side toward the tip portion (emission face) 154a. More specifically, the side faces of the columnar optical portion 154 have an arbitrary angle of inclination θ from approximately 0 degrees to 20 degrees relative to the centerline C11 of the columnar optical portion 154. In other words, the columnar optical portion 154 gradually becomes wider moving upward from the emission face 154a at an angle equal to the angle of inclination θ (0 degrees<θ≦20 degrees), and therefore the upper end face 154b of the columnar optical portion 154 has a larger surface area than that of the emission face 154a of the columnar optical portion 154 and furthermore the light receiving face 101a of the solar cell element 101. Also, the columnar optical portion 154 is formed with a size according to which the emission face 154a (tip portion 154a) is located within the light receiving face 101a of the solar cell element 101.

The sealing portions 12 each have a configuration similar to that of the sealing portion 12 of Embodiments 1 and 2 described above. Specifically, each sealing portion 12 is formed by transparent insulating resin (e.g., at least one resin material from among silicone resin, acrylic resin, fluorine resin, and epoxy resin) that fills the space between the solar cell element 101 and the optical member 14 (tip portion 154a of the columnar optical portion 154 in each optical portion 15), and is configured such that the light receiving face 101a of the solar cell element 101 is irradiated with the concentrated sunlight Lsc. Note that it is desirable that the insulating resin that is used in the sealing portion 12 has an internal transmissivity of 99.9% or more with respect to the wavelength band of 300 nm to 2000 nm. Also, the smaller the difference in refractive index is from the refractive index of the material forming the optical member 14, the better, and a transparent silicone resin having a refractive index of approximately 1.4, for example, can be favorably used. Also, by sealing the tip portion 154a of the columnar optical portion 154 and the solar cell element 101 by adhesion using the sealing portion 12 (i.e., adhering the concentrated light emission portion 153 and the solar cell element 101 together with the insulating resin (adhesive material)), it is possible to prevent the entrance of moisture and water into the solar cell element 101, thus enabling improving the reliability and weather resistance.

Similarly to the optical member 13 of Embodiments 1 and 2, the optical portions 15 of the optical member 14 are configured so as to always directly face the sun through the operation of a tracking mechanism (not shown) for tracking the sun. Accordingly, the sunlight Ls is always incident in the perpendicular direction along a centerline C1 (see FIG. 10) of the entrance face 151a of the optical portion 15. The sunlight Lsc that is incident on the optical portion 15 is refracted by the dome-shaped optical refraction portion 151, passes through the interior of the optical base portion 152, and is emitted onto the light receiving face 101a of the solar cell element 101.

Similarly to the concentrated solar cells 1A and 1B of Embodiments 1 and 2, the concentrated solar cell 1C of Embodiment 3 is configured so as to not have the intermediate air layer 63 (see FIGS. 13 and 14) that exists in conventional concentrated solar cells, and therefore sunlight that is incident on the optical member 14 somewhat deviated from the perpendicular direction also passes through the interior of the optical base portion 152 and is guided onto the light receiving face 101a of the solar cell element 101. Here, the sunlight concentrated by the dome-shaped optical refraction portion 151 has a low angle of refraction since it is concentrated by undergoing refraction one time at the entrance face 151a, which is the boundary portion between the air layer, which is a low refractive index portion, and the optical refraction portion 151, which is a high refractive index portion. As a result, the amount of misalignment of the spot position of the concentrated light focal point group 30 occurring due to several degrees of tracking error is also lower than the amount of misalignment of the spot position of the concentrated light focal point group 30 in conventional concentrated solar cells, and therefore it is possible to improve the output stability, reliability, and weather resistance of the concentrated solar cell.

Similarly to the concentrated solar cells 1A and 1B of Embodiments 1 and 2, each solar cell element 101 of the concentrated solar cell 1C of Embodiment 3 is designed so as to be larger than the spot size of the concentrated light focal point group 30. Specifically, it is configured such that the spot position of the concentrated light focal point group 30 is located within the light receiving face 101a of the solar cell element 101. Accordingly, even if sunlight somewhat deviates from the perpendicular direction due to several degrees of tracking error, the spot position of the emitted concentrated light focal point group 30 does not deviate from the light receiving face 101a of the solar cell element 101.

Accordingly, with the concentrated solar cell 1C of Embodiment 3 that uses the optical member 14, there is no reduction in output even if several degrees of tracking error arises. Since the receiver substrate 102 is not irradiated by the concentrated light focal point group 30, it is possible to prevent the members arranged on the surface of the receiver substrate 102 from being burned, and to obtain a high-efficiency and high-quality concentrated solar cell.

Furthermore, similarly to the optical member 13 of Embodiment 2, due to the optical portion 15 of the optical member 14 of Embodiment 3 being configured such that the columnar optical portion 154 is provided on the concentrated light emission portion 153, the concentrated light (sunlight Lsc) that is incident on the columnar optical portion 154 is guided to the light receiving face 101a of the solar cell element 101 due to repeatedly undergoing total reflection at the side faces of the columnar optical portion 154, thus eliminating chromatic aberration on the light receiving face 101a of the solar cell element 101 and making it possible to also eliminate fluctuation in the intensity of the sunlight Lsc. This makes it possible to further improve the output of the solar cell.

Also, the columnar optical portion 154 is provided such that the spot position of the concentrated light focal point group 30 of the sunlight concentrated by the optical portion 15 of the optical member 14 is positioned within the upper end face 154b. In other words, the upper end face 154b of the columnar optical portion 154 is designed so as to be larger than the spot size of the concentrated light focal point group 30. Accordingly, even if there is sunlight that is incident somewhat deviated from the perpendicular direction due to several degrees of tracking error, or misalignment occurs when the optical member 14 is assembled, the sunlight is incident on the columnar optical portion 154, repeatedly undergoes total reflection at the side faces of the columnar optical portion 154, and is then entirely emitted on the light receiving face 101a of the solar cell element 101, thus making it possible to obtain the high-quality and high-efficiency concentrated solar cell 1B.

Also, the optical portions 15 of the optical member 14 each have an integrated structure in which there is no intermediate air layer from the optical refraction portion 151 to the concentrated emission portion 153 with the optical base portion 152 therebetween, and the optical base portion 152 is shaped as a prism with the square-shaped concentrated light exit portion 153 as the bottom face. According to this structure, an outer diameter portion of the optical base portion 152 of the optical member 14 in the periphery of the concentrated light emission portion 153 does not serve as an optical path for the sunlight Lsc that is refracted and concentrated by the optical refraction portion 151. In other words, the outer peripheral faces of the optical base portion 152 are arranged outside the optical path of the concentrated sunlight Lsc. This enables the portion of the optical base portion 152 in the periphery of the concentrated light emission portion 153 to be used as a support portion.

Also, similarly to the optical member 13 of Embodiments 1 and 2, the outer diameter portion of the optical member 14 of Embodiment 3 is supported by the support member 11A on which the solar cell substrate 10A is placed, thus allowing the sunlight Ls to be incident on the optical refraction portion 151 without loss.

Also, the support member 11A, which has a configuration similar to that of the support member 11A shown in FIG. 5, has a support part 112A that is constituted by a base part 113A and a support claw 114A that are formed in the shape of a square in a plan view so as to conform to the outer peripheral shape of the optical member 14. Specifically, in this configuration, the base part 113A is formed in the shape of a four-cornered frame with an open upper portion, and the support claw 114A, which has an L-shaped cross-section, is formed in the shape of a ring that conforms to the inner peripheral wall side of the upper face portion of the frame.

The concentrated solar cell 1C of Embodiment 3 enables eliminating the intermediate air layer that exists in the structure of conventional concentrated solar cells. Specifically, it is possible to eliminate a reduction in performance caused by light intensity reflection that occurs as a result of a large difference between refractive indices caused by the existence of an intermediate air layer, thus enabling improving the output of the concentrated solar cell.

With a configuration in which multiple concentrated solar cells 1A or 1B of Embodiment 1 or 2 are arranged in the row direction and the column direction, and multiple solar cell elements 101 are mounted, the optical member 13 of each concentrated solar cell 1A or 1B is supported by a respective support member 11 or 11A, and therefore gaps are formed between the optical members 13. Sunlight that is incident on the gaps between the optical members 13 of the concentrated solar cells 1A or 1B is not received by the solar cell elements 101, and therefore sunlight loss occurs due to the gaps between the optical members 13 in a configuration in which multiple concentrated solar cells 1A or 1B of Embodiment 1 or 2 are arranged in the row direction and the column direction. In contrast, the concentrated solar cell 1C of Embodiment 3 is configured such that multiple solar cell elements 101 are mounted on one receiver substrate 102, the optical member 14 is obtained by forming a continuous array of multiple optical portions 15 without gaps in correspondence with the solar cell elements 101 (i.e., the entire surface of the optical member 14 is an effective optical area), and the optical member 14 is supported by one support member 11A (the support member 11A on which the receiver substrate 102 is placed), and therefore the above-described sunlight loss due to gaps does not occur.

The following describes a method for manufacturing the concentrated solar cell 1C of Embodiment 3.

Step 1: First, the optical member 14 is prepared (optical member preparation step).

The optical member 14 that is to be prepared is preferably manufactured using optical glass having favorable transmissivity in view of weather resistance and reliability. In order to form the optical refraction portion 151 so as to allow the sunlight Ls to efficiently be incident on the solar cell element 101, the optical member 14 is manufactured by molding or milling. Note that there is no limitation to these methods.

It should also be noted that the optical portions 15 of the optical member 14 may be formed all at once by molding or milling, and a configuration is possible in which multiple optical portions 15 are individually formed by molding or milling, and then the optical portions 15 are integrated by the side faces of the optical portions 15 being by adhered together using transparent resin or an optical contact.

Also, the columnar optical portion 154, the optical refraction portion 151, and the optical base portion 152 may be formed all at once by molding or milling, and a configuration is possible in which the optical refraction portion 151 and the optical base portion 152 are formed by molding or milling and then the columnar optical portion 154 is adhered to the concentrated light emission portion 153, which is the bottom face of the optical base portion 152, using transparent resin or an optical contact.

Also, in consideration of weight reduction and cost reduction, the optical member 14 can be manufactured using silicone resin, acrylic resin, plastic, or the like.

Step 2: Next, the solar cell elements 101 are mounted on the receiver substrate 102 (receiver substrate preparation step).

The receiver substrate 102 is a substrate obtained by connecting electrodes (not shown) of the solar cell elements 101 to a base foundation such as an aluminum plate or a copper plate, which additionally functions as an electrode, via an appropriate insulating layer made of a ceramic, glass, or the like. The solar cell elements 101 are precisely arranged on the base foundation and then adhered and fixed thereto using solder, electrode paste, or the like.

Note that due to demand for high efficiency and practical utility, it is desirable for the solar cell elements 101 applied to the concentrated solar cell to be a triple junction solar cell element constituted by InGaP/GaAs/Ge, a solar cell element constituted by AlGaAs/Si, or a monolithic multi-junction solar cell element.

Step 3: Next, the receiver substrate 102 is placed on the support member 11A (receiver substrate mounting step).

As described above, the base part 113A of the support member 11A also functions as a positioning member for precisely placing the receiver substrate 102 on the support substrate 111A, and therefore the receiver substrate 102 can be precisely placed merely dropping it into the space inside the base part 113A so as to be fitted therein. Thereafter, the receiver substrate 102 is fixed onto the support substrate 111A by, for example, adhesion using solder or a resin such as an adhesive material, for example, or mechanical holding using screw fixing or the like.

Step 4: Next, multiple sealing portions 12 are formed on the receiver substrate 102 such that the solar cell elements 101 on the receiver substrate 102 are individually covered by sealing portions 12 (sealing step).

It is desirable for the sealing portions 12 to each be formed from silicone resin, acrylic resin, an adhesive material, or the like that have favorable transmissivity and favorable adhesion to the optical member 14. Since resin and the like have fluidity, it is preferable that a metal frame or plastic frame is formed, the metal frame or plastic frame is placed on the receiver substrate 102 so as to surround the solar cell element 101, and then the frame is filled with a predetermined amount of resin.

Step 5: Next, the optical member 14 is mounted on the support member 11A (optical member mounting step).

After the receiver substrate 102 is placed on the support substrate 111A, the optical member 14 is placed on the support member 11A by placing the outer diameter portion of the optical member 14 in the space between the support claw 114A of the support part 112A from above. This placement alone enables precisely aligning the centers of the solar cell elements 101 of the receiver substrate 102 and the centers of the concentrated light emission portions 153 of the optical portions 15 of the optical member 14.

Step 6: Next, the optical member 14 (optical portions 15) and the sealing portions 12 are adhered together (sealing portion integrated optical system adhesion step).

While the optical member 14 is placed on the support member 11A, the emission faces 154a of the columnar optical portions 154 of the optical portions 15 of the optical member 14 are in contact with the sealing portions 12. Also, the resin used for the sealing portions 12 is generally a thermal-curing or air-setting resin. Accordingly, by curing the resin according to its specification, the sealing portions 12 can be adhered to the emission faces 154a of the columnar optical portions 154 of the optical portions 15 of the optical member 14 in contact with the resin.

This enables manufacturing the concentrated solar cell 1C in which the solar cell substrate 10A, the support member 11A, the sealing portions 12, and the optical member 14 are integrated.

Note that although the optical refraction portion 151 is dome-shaped in Embodiment 3, it may be a Fresnel lens-shaped optical refraction portion. In this case, the entrance face 152a of the optical base portion 152 is formed so as to conform to the shape of a lens face that is the lower face of the optical refraction portion.

Also, although nine solar cell elements 101 are mounted on the receiver substrate 102 and the optical member 14 has nine optical portions 15 corresponding to the solar cell elements 101 in the configuration of Embodiment 3, there are no particular limitations on the number of solar cell elements 101 mounted on the receiver substrate 102 and the number of optical portions 15 in the optical member 14. For example, a configuration is possible in which an optical member 14 having the maximum number of optical portions 15 that can be formed all at once by molding (injection molding) is manufactured, and the same number of solar cell elements 101 as the number of optical portions 15 of the optical member 14 are mounted on the receiver substrate 102.

Also, although the optical portions 15 of the optical member 14 of Embodiment 3 have a configuration similar to that of the optical member 13 of Embodiment 2, the optical portions 15 may have a configuration similar to the optical member 13 of Embodiment 1, that is to say, may be configured so as to not include the columnar optical portion 154.

Also, although the optical member 14 of Embodiment 3 is supported by the support member 11A having a configuration similar to that of the support member 11A shown in FIG. 5, it may be supported by a support member 11 having a configuration similar to that of the support member 11 shown in FIG. 1. In this case, the distance L1 between the side face support portions 114b of a pair of support parts 112 arranged so as to oppose each other across the substrate center P of the support member 11 is substantially the same as a width W5 between opposing side faces of the outer diameter portion of the optical member 14, and the outer diameter portion of the optical member 14 is supported so as to not be horizontally misaligned when fitted in between the side face support portions 114b of the opposing support pieces 114.

Also, the embodiments disclosed here are to be considered as examples in all respects, and are not to serve as grounds for a limiting interpretation. Accordingly, the technical scope of the invention is not to be interpreted based on only the above-described examples, but rather is defined by the recitation of the claims. Also, all changes that come within the meaning and range of equivalency of the claims are intended to be embraced therein.

In other words, the invention can be embodied in various other forms without departing from the spirit or essential characteristics thereof. The foregoing embodiments are therefore to be interpreted in all respects as merely illustrative and not restrictive. The scope of the invention is indicated by the appended claims rather than by the foregoing description. Furthermore, all modifications and changes that come within the meaning and range of equivalency of the claims are intended to be embraced therein.

Also, this application claims priority based on JP 2011-113815A submitted in Japan on May 20, 2011. The contents thereof are herein incorporated in the present application by reference.

### DESCRIPTION OF REFERENCE NUMERALS

1A, 1B Concentrated solar cell
10, 10A Solar cell substrate
101 Solar cell element
102 Receiver substrate (element substrate)
11 Support member
111 Support substrate
112 Support part
113 Base part
114 Support claw
114a Bottom face support portion
114b Side face support portion
12 Sealing portion
13 Optical member
131, 138 Optical refraction portion
132 Optical base portion
133 Concentrated light emission portion
134 Columnar optical portion
134a Tip portion (emission face)
134b Upper end portion (upper end face)
136 Optical outer diameter portion
138b Lens face
14 Optical member
15 Optical portion
151 Optical refraction portion
152 Optical base portion
153 Concentrated light emission portion
154 Columnar optical portion
154a Tip portion (emission face)
154b Upper end portion (upper end face)
30,30′ Concentrated light focal point group
50 Concentrating lens
62 Optical refraction portion
63 Intermediate air layer
70 Solar cell
701 Receiver substrate
702 Solar cell element
702a Light receiving face
703 Cover glass
704 Sealing resin
90 Module frame

1. A concentrated solar cell comprising an element substrate, a solar cell element provided on the element substrate, a sealing portion provided on the element substrate so as to cover the solar cell element, and an optical member that is provided on the sealing portion and concentrates sunlight on the solar cell element,
the optical member being configured so as to include:
an optical refraction portion that has a curved face for refracting and concentrating sunlight;
a concentrated light emission portion that is arranged in close contact with the sealing portion such that sunlight concentrated by the optical refraction portion is emitted toward the solar cell element; and
an optical base portion arranged between the optical refraction portion and the concentrated light emission portion, and
the optical member being an integrated structure in which there is no intermediate air layer from the optical refraction portion to the concentrated light emission portion with the optical base portion therebetween.

2. The concentrated solar cell according to claim 1, comprising: a plurality of the solar cell elements; a plurality of the sealing portions individually and respectively covering the solar cell elements; and the optical member concentrating sunlight on each of the solar cell elements,
the optical member having a plurality of optical portions that respectively correspond to the plurality of solar cell elements provided on the element substrate,
the optical portions each including:
an optical refraction portion that has a curved face for refracting and concentrating sunlight;
a concentrated light emission portion that is arranged in close contact with one of the sealing portions such that sunlight concentrated by the optical refraction portion is emitted toward one of the solar cell elements; and
an optical base portion arranged between the optical refraction portion and the concentrated light emission portion, and
the optical portions each being an integrated structure in which there is no intermediate air layer from the optical refraction portion to the concentrated light emission portion with the optical base portion therebetween.

3. The concentrated solar cell according to claim 1, wherein an outer peripheral face of the optical base portion is arranged outside an optical path of refracted light obtained when sunlight that is incident on a light receiving face of the solar cell element is refracted by the optical refraction portion.

4. The concentrated solar cell according to claim 1, wherein the curved face of the optical refraction portion is dome-shaped or Fresnel lens-shaped.

5. The concentrated solar cell according to claim 1, the optical member is formed from a glass material or at least one resin material from among silicone resin, acrylic resin, fluorine resin, and epoxy resin.

6. The concentrated solar cell according to claim 1,
wherein the optical member is formed from a glass material with a refractive index of 1.5 to 1.7, and
the ratio of the width of the concentrated light emission portion to the length from a top portion of the optical refraction portion to the concentrated light emission portion is 1:1.5 to 1:3.

7. The concentrated solar cell according to claim 1, wherein a spot position of a concentrated light focal point group of sunlight concentrated by the optical member is located within the light receiving face of the solar cell element.

8. The concentrated solar cell according to claim 1, wherein the concentrated light emission portion and the solar cell element are adhered together using at least one adhesive material from among silicone resin, acrylic resin, fluorine resin, and epoxy resin.

9. The concentrated solar cell according to claim 1, wherein a columnar optical portion is formed on the concentrated light emission portion, and the portion of the concentrated light emission portion that is arranged in close contact with the sealing portion is a tip portion of the columnar optical portion.

10. The concentrated solar cell according to claim 9, wherein the columnar optical portion is provided so as to gradually decrease in cross-sectional size from an upper end portion on the concentrated light emission portion side toward the tip portion.

11. The concentrated solar cell according to claim 9, wherein a peripheral side face of the columnar optical portion has an angle of inclination of 0 degrees to 20 degrees relative to a centerline of the columnar optical portion.

12. The concentrated solar cell according to claim 9, wherein the tip portion of the columnar optical portion and the solar cell element are adhered together using at least one adhesive material from among silicone resin, acrylic resin, fluorine resin, and epoxy resin.

13. The concentrated solar cell according to claim 9, wherein a spot position of a concentrated light focal point group of sunlight concentrated by the optical member is located within an upper end face of the columnar optical portion.

14. The concentrated solar cell according to claim 9, wherein the tip portion of the columnar optical portion is formed with a size according to which the tip portion is located within the light receiving face of the solar cell element.

15. The concentrated solar cell according to claim 1, wherein the solar cell element is a compound multi-junction solar cell.

16. The concentrated solar cell according to claim 1, comprising a support member that supports and fixes the optical member on the element substrate.

17. The concentrated solar cell according to claim 16, wherein the support member comprises a support substrate on which the element substrate is placed, and a support part that is provided upright on the support substrate and supports an outer peripheral portion of a lower portion of the optical member.

18. The concentrated solar cell according to claim 17, wherein the support part additionally functions as a positioning member that places the element substrate at a precise position on the support substrate.

19. A manufacturing method for a concentrated solar cell in which a solar cell element is provided on an element substrate, a sealing portion is provided on the element substrate so as to cover the solar cell element, an integrated-structure optical member that concentrates sunlight on the solar cell element is provided on the sealing portion, and the element substrate and the optical member are integrally supported and fixed by a support member, the method comprising:
a step of mounting the solar cell element on the element substrate;
a step of placing the element substrate, on which the solar cell element is mounted, on a support substrate of the support member;
a step of forming the sealing portion on an upper portion of the solar cell element;
a step of supporting the optical member using a support part provided on the support substrate; and
a step of adhering and fixing the sealing portion and the optical member using an adhesive material.

20. A manufacturing method for a concentrated solar cell in which a plurality of solar cell elements are provided on an element substrate, a plurality of sealing portions are provided on the element substrate so as to individually and respectively cover the solar cell elements, an optical member having a plurality of integrated-structure optical portions that respectively correspond to the solar cell element and concentrate sunlight on the respective solar cell elements is provided on the sealing portions, and the element substrate and the optical member are integrally supported and fixed by a support member, the method comprising:
a step of mounting the plurality of solar cell elements on the element substrate;
a step of placing the element substrate, on which the plurality of solar cell elements are mounted, on a support substrate of the support member;
a step of forming the sealing portions on upper portions of the respective solar cell elements;
a step of supporting the optical member using a support part provided on the support substrate; and
a step of adhering and fixing the sealing portions and the optical member using an adhesive material.
